(19) United States
(12) Patent Application Publication
(10) Pub. No.: US 2023/0261164 A1
(43) Pub. Date: Aug. 17, 2023

(54) TRANSPARENT ELECTRONIC DEVICE, LAMINATED GLASS, AND MANUFACTURING METHOD OF TRANSPARENT ELECTRONIC DEVICE

(71) Applicant: AGC Inc., Tokyo (JP)

(72) Inventors: Masahide KOGA, Chiyoda-ku (JP); Yukihiro TAO, Chiyoda-ku (JP); Remi KAWAKAMI, Chiyoda-ku (JP)

(73) Assignee: AGC Inc., Tokyo (JP)

(21) Appl. No.: 18/302,864

(22) Filed: Apr. 19, 2023

Related U.S. Application Data
(63) Continuation of application No. PCT/JP2021/039226, filed on Oct. 25, 2021.

(30) Foreign Application Priority Data
Oct. 28, 2020 (JP) 2020-180421

(51) Int. Cl. H01L 33/62; H01L 25/075; B60J 1/00; G09F 9/33; B32B 17/10; B32B 1/00

(52) U.S. Cl. CPC H01L 33/62; H01L 25/0753; B60J 1/00; G09F 9/33; B32B 17/10036; B32B 1/00; H01L 2933/0066; B32B 2605/00; B32B 2307/7376; B32B 2457/20

(57) ABSTRACT

A transparent electronic device, including: a transparent insulating substrate (TIS); an electronic element which is formed on a main surface of the TIS and which has an area of 250,000 μm² or less; and an opaque power feeder configured to feed power to the electronic element. The electronic element is a light-emitting diode element or a sensor. The TIS includes: a first TIS with the electronic element and a first wiring connected to the electronic element being formed on one main surface; and a second TIS with a second wiring being formed on one main surface, the electronic element is not formed on the second TIS, and one end of the first wiring and one end of the second wiring are electrically connected to each other and the opaque power feeder is connected to another end of the second wiring in an edge part of the second TIS.

### INCORPORATION BY REFERENCE

This application is based upon and claims the benefit of priority from Japanese Patent Application No. 2020-180421 filed on Oct. 28, 2020 and PCT application No. PCT/JP2021/039226 filed on Oct. 25, 2021, the disclosure of which is incorporated herein in its entirety by reference.

### BACKGROUND

The present invention relates to a transparent electronic device, a laminated glass, and a manufacturing method of the transparent electronic device.

As disclosed in International Patent Publication No. WO 2019/146634, the present inventors have developed a transparent display device which uses, in a pixel, fine light-emitting diode (LED) elements formed on a transparent insulating substrate. Since a rear-face side of such a transparent display device is visible via the transparent display device, for example, the transparent display device is provided in transparent members such as windows, partitions, or the like of vehicles and buildings. As a related technique, a transparent sensing device in which a microsensor is provided on a transparent insulating substrate is known.

In the present specification, an electronic device in which an electronic element is formed on a transparent insulating substrate and of which a rear-face side is visible such as a transparent display device or a transparent sensing device will be referred to as a “transparent electronic device”.

### SUMMARY

The present inventors have found the following problems with respect to such transparent electronic devices.

Since a power feeder (for example, a flexible wiring board) for feeding power to the transparent electronic device is opaque, the power feeder is connected to an edge part of the transparent electronic device. Therefore, there is a problem in that, depending on an arrangement position of an electronic element in a transparent member such as a window, a routing distance of a fine wiring connecting the electronic element and the power feeder to each other increases (in other words, an area of the transparent electronic device increases) and yield of the transparent electronic device declines.

The present invention provides a transparent electronic device configured as described in [1] below.

[1]

A transparent electronic device, including:

a transparent insulating substrate;

an electronic element which is formed on a main surface of the transparent insulating substrate and which has an area of 250,000 μm² or less; and

an opaque power feeder configured to feed power to the electronic element, wherein

the electronic element is a light-emitting diode element or a sensor,

the transparent insulating substrate includes:

a first transparent insulating substrate with the electronic element and a first wiring connected to the electronic element being formed on one main surface; and

a second transparent insulating substrate with a second wiring being formed on one main surface,

the electronic element is not formed on the second transparent insulating substrate, and

one end of the first wiring and one end of the second wiring are electrically connected to each other and the opaque power feeder is connected to another end of the second wiring in an edge part of the second transparent insulating substrate.

In an aspect of the present invention,

[2] the transparent electronic device according to [1], in which the first transparent insulating substrate and the second transparent insulating substrate overlap with each other in a plan view, and the one end of the first wiring and the one end of the second wiring are electrically connected to each other in the overlapping portion of the first transparent insulating substrate and the second transparent insulating substrate.
[3] The transparent electronic device according to [2], in which all of the first transparent insulating substrate overlaps with the second transparent insulating substrate in a plan view.
[4] The transparent electronic device according to [2] or [3], in which the one main surface of the first transparent insulating substrate and the one main surface of the second transparent insulating substrate oppose each other and overlap with each other in a plan view.
[5] The transparent electronic device according to any one of [1] to [4], in which a region where the electronic element is arranged in the first transparent insulating substrate does not overlap with the second wiring.
[6] The transparent electronic device according to any one of [1] to [5], in which the electronic element is a light-emitting diode element, and the light-emitting diode element constitutes a transparent display device.
[7] The transparent electronic device according to any one of [1] to [6], in which the second transparent insulating substrate is flexible.
[8] The transparent electronic device according to any one of [1] to [7], in which the one end of the first wiring and the one end of the second wiring are electrically connected to each other via a conductive joining layer.
[9]

A laminated glass, including:

a pair of glass plates arranged so as to oppose each other; and

first and second interlayers provided between the pair of glass plates, in which

the transparent electronic device according to any one of [1] to [8] is sandwiched between the first and second interlayers.

[10] The laminated glass according to [9], in which a shielding layer is formed on a peripheral edge of at least one of the pair of glass plates.
[11] The laminated glass according to [10], in which an opaque wiring region in which at least one of the first and second wirings is formed wide and which is opaque is formed on a peripheral edge of the transparent electronic device, and the opaque wiring region is installed so as to overlap with the shielding layer in a plan view.
[12] The laminated glass according to [10] or [11], in which the opaque power feeder is installed so as to overlap with the shielding layer in a plan view.
[13] The laminated glass according to any one of [10] to [12], in which a peripheral edge of at least one of the first and second transparent insulating substrates is installed so as to overlap with the shielding layer in a plan view.
[14] The laminated glass according to any one of [9] to [13], in which a protective layer which covers the first transparent insulating substrate is formed between the first and second interlayers.
[15] The laminated glass according to [14], in which the protective layer includes an interlayer which differs from the first and second interlayers.
[16] The laminated glass according to any one of [9] to [15], in which the pair of glass plates are curved.
[17] The laminated glass according to any one of [9] to [16], in which the laminated glass is for a vehicle, and a thickness of a glass plate positioned on a vehicle exterior side among the pair of glass plates ranges from 1.5 mm to 3.0 mm.
[18] The laminated glass according to any one of [9] to [17], in which a peripheral edge of the first transparent insulating substrate does not overlap with the “Test region A” as defined in Annex “Test regions for optical properties and light resistance tests of safety glass” of JIS Standard R3212:2015 (Test methods of safety glazing materials for road vehicles) in a plane view.
[19] The laminated glass according to any one of [9] to [18], in which a peripheral edge of the second transparent insulating substrate does not overlap with the “Test region A” as defined in Annex “Test regions for optical properties and light resistance tests of safety glass” of JIS Standard R3212:2015 (Test methods of safety glazing materials for road vehicles) in a plane view.

The present invention provides a manufacturing method of a transparent electronic device configured as described in [20] below.

[20]

A manufacturing method of a transparent electronic device, including:

forming an electronic element which has an area of 250,000 μm² or less and a first wiring which is connected to the electronic element on one main surface of a first transparent insulating substrate;

forming a second wiring without forming the electronic element on one main surface of a second transparent insulating substrate; and

electrically connecting one end of the first wiring and one end of the second wiring to each other and connecting an opaque power feeder which feeds power to the electronic element to another end of the second wiring in an edge part of the second transparent insulating substrate.

According to the present invention, a transparent electronic device with superior yield can be provided.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF THE DRAWINGS

FIG. 1 is a schematic plan view showing an example of a transparent display device according to a first embodiment.

FIG. 2 is a sectional view taken along a cut line II-II in FIG. 1.

FIG. 3 is a schematic partial plan view showing an example of a display region 101.

FIG. 4 is a sectional view taken along a cut line IV-IV in FIG. 3.

FIG. 5 is a sectional view showing an example of a manufacturing method of the transparent display device according to the first embodiment.

FIG. 6 is a sectional view showing an example of a manufacturing method of the transparent display device according to the first embodiment.

FIG. 7 is a sectional view showing an example of a manufacturing method of the transparent display device according to the first embodiment.

FIG. 8 is a sectional view showing an example of a manufacturing method of the transparent display device according to the first embodiment.

FIG. 9 is a sectional view showing an example of a manufacturing method of the transparent display device according to the first embodiment.

FIG. 10 is a sectional view showing an example of a manufacturing method of the transparent display device according to the first embodiment.

FIG. 11 is a sectional view showing an example of a manufacturing method of the transparent display device according to the first embodiment.

FIG. 12 is a sectional view showing an example of a manufacturing method of the transparent display device according to the first embodiment.

FIG. 13 is a schematic sectional view showing a transparent display device according to a first modified example of the first embodiment.

FIG. 14 is a schematic sectional view showing a transparent display device according to a second modified example of the first embodiment.

FIG. 15 is a schematic sectional view showing a transparent display device according to a third modified example of the first embodiment.

FIG. 16 is a schematic sectional view showing a transparent display device according to a fourth modified example of the first embodiment.

FIG. 17 is a schematic plan view showing an example of a laminated glass according to a second embodiment.

FIG. 18 is a sectional view taken along a cut line XVIII-XVIII in FIG. 17.

FIG. 19 is a schematic sectional view showing another example of a laminated glass according to the second embodiment.

FIG. 20 is a schematic partial plan view showing an example of a transparent display device according to a third embodiment.

FIG. 21 is a schematic partial plan view showing an example of a transparent sensing device according to a fourth embodiment.

FIG. 22 is a schematic sectional view of a sensor 70.

### DESCRIPTION OF EMBODIMENTS

Hereinafter, specific embodiments to which the present invention has been applied will be described in detail with reference to the drawings. However, the present invention is not limited to the following embodiments. In addition, for the sake of brevity, the following descriptions and the drawings have been simplified as appropriate.

In the present specification, a “transparent display device” refers to a display device which causes visual information related to a person, a background, or the like positioned on a rear-face side of the display device to be visually recognizable under a desired use environment. Note that whether or not visually recognizable is determined in a state where at least the display device is not displayed or, in other words, the display device is not energized.

In a similar manner, in the present specification, a “transparent sensing device” refers to a sensing member which causes visual information related to a person, a background, or the like positioned on a rear-face side of the sensing device to be visually recognizable under a desired use environment. A “sensing device” refers to a device capable of acquiring various kinds of information using a sensor.

In the present specification, “transparent” refers to transmittance of visible light being 40% or higher, preferably 60% or higher, and more preferably 70% or higher. Alternatively, “transparent” may refer to transmittance being 5% or higher and a haze value being 10 or smaller. A transmittance of 5% or higher enables outdoors to be viewed with a brightness equal to or higher than indoors when the outdoors is viewed from indoors during the day and enables superior visibility to be secured.

In addition, a transmittance of 40% or higher enables the rear-face side of the transparent display device to be substantially visually recognized without incident even when brightness on a front-face side and brightness on the rear-face side of the transmittance are more or less the same. Furthermore, a haze value of 10 or smaller enables contrast of the background to be sufficiently secured.

“Transparency” is realized regardless of whether color is imparted or not or, in other words, “transparent” may refer to being colorless and transparent or being colored and transparent.

Note that transmittance refers to a value (%) measured by a method conforming to ISO 9050. A haze value refers to a value measured by a method conforming to ISO 14782.

### First Embodiment

### <Configuration of Transparent Display Device>

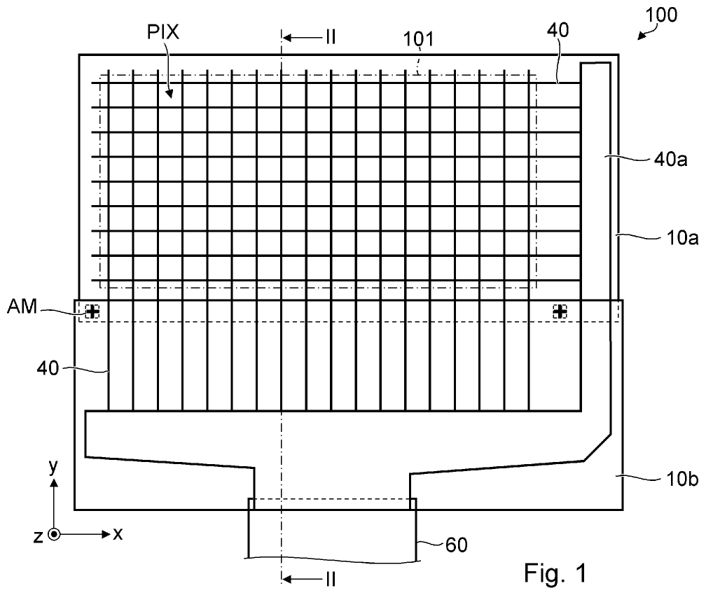

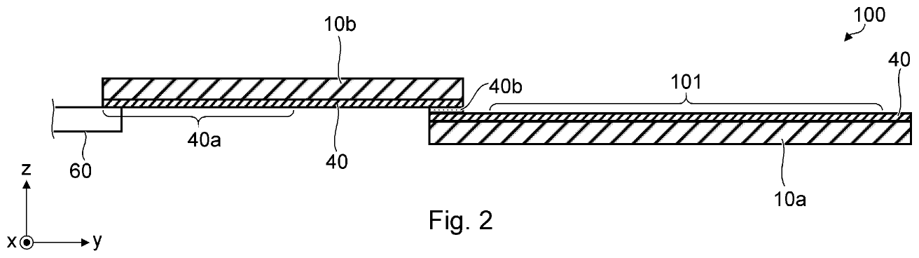

First, a configuration of a transparent display device according to a first embodiment will be explained with reference to FIG. 1 and FIG. 2. FIG. 1 is a schematic plan view showing an example of the transparent display device according to the first embodiment. FIG. 2 is a sectional view taken along a cut line II-II in FIG. 1. The transparent display device is an aspect of the transparent electronic device.

It should be understood that right-handed system xyz orthogonal coordinates shown in FIG. 1 and the other drawings are provided for the sake of convenience in order to explain positional relationships among constituent elements. Usually, conventions shared among the drawings include a z-axis positive direction being vertically upward and an xy plane being a horizontal plane.

As shown in FIG. 1 and FIG. 2, a transparent display device 100 according to the first embodiment includes transparent insulating substrates 10a and 10b and a flexible wiring board 60.

In this case, as shown in FIG. 1, the transparent display device 100 includes a display region 101. The display region 101 is a region which is constituted of a plurality of pixels PIX and in which images are to be displayed. Note that images include characters. Although details will be provided later, each pixel PIX includes at least one light-emitting diode element (hereinafter, an LED element). In other words, the transparent display device according to the present embodiment is a display device using a fine LED element in each pixel and is referred to as an LED display or the like.

LED elements are not formed in a non-display region outside of the display region 101.

Note that an organic EL (electro-luminescence) display and an inorganic EL (electro-luminescence) display are also included in LED displays including LED elements.

The transparent insulating substrate 10a (the first transparent insulating substrate) includes the display region 101, and a wiring 40 and an LED element connected to the wiring 40 are formed on one main surface of the transparent insulating substrate 10a. In this case, the LED element is an example of a fine electronic element having an area of 250,000 μm² or less.

The transparent insulating substrate (the second transparent insulating substrate) 10b does not include the display region 101, and the wiring 40 is formed but an LED element is not formed on one main surface of the transparent insulating substrate 10b. In addition, an LED element is also not formed on another main surface of the transparent insulating substrate 10b.

In other words, the transparent insulating substrate 10a includes all of the display region 101 and the transparent insulating substrate 10b does not include the display region 101. Furthermore, only the wiring 40 is formed on the transparent insulating substrate 10b. Alternatively, in addition to the wiring 40, only an electronic element other than an LED element and a sensor to be described later may be formed on the transparent insulating substrate 10b.

In this case, the wiring 40 linearly shown in FIG. 1 extends in an x-axis direction and a y-axis direction. The wiring 40 extending in the x-axis direction widens in an end part on a side of a positive x-axis direction of the transparent insulating substrates 10a and 10b, extends in a negative y-axis direction, and is connected to the flexible wiring board 60. In other words, in the wiring 40, at least a part of a portion extended in the negative y-axis direction is wider than a portion extended in the x-axis direction. In addition, the wiring 40 extended in the y-axis direction widens in an end part on a side of a negative y-axis direction of the transparent insulating substrate 10b, and is connected to the flexible wiring board 60. In other words, in a portion of the wiring 40 extended in the y-axis direction, a width at one end in the negative y-axis direction is wider than a width at one end in the positive y-axis direction.

In FIG. 1, an opaque region in which the wiring 40 is formed with a large width is schematically shown as an opaque wiring region 40a. In reality, in the opaque wiring region 40a, the wide wiring 40 is provided as a group of closely packed wirings. Therefore, at least a part of a portion of the wiring 40 extended in the opaque wiring region 40a can be described as being wider than a portion extended in the display region 101. Note that portions of the wiring 40 in the x-axis direction (the display region part) and the y-direction (the opaque wiring region 40a) may have approximately the same width and the wiring 40 may form a mesh-like wiring group in the opaque wiring region 40a. The opaque wiring region 40a may be provided with a driver IC (integrated circuit) for driving the LED element or an element as a measure for electrostatic discharge.

Note that as will be described later, each wiring 40 drawn as a single line in FIG. 1 is constituted of a plurality of fine wirings.

Although details will be provided later, a width of the fine wiring 40 is, for example, 1 μm to 100 μm and, preferably, 3 μm to 20 μm. Since the width of the wiring 40 is 100 μm or less, for example, even when the transparent display device is observed from a short distance of around several 10 cm to 2 m, the wiring 40 is hardly visually recognizable and superior visibility of the rear-face side can be secured.

On the other hand, a width of the wiring 40 in the opaque wiring region 40a is, for example, 100 μm to 10,000 μm and, preferably, 100 μm to 5,000 μm. Intervals between the wirings are, for example, 3 μm to 5,000 μm and, preferably, 50 μm to 1,500 μm. The wiring 40 in the opaque wiring region 40a is visually recognizable. Therefore, the opaque wiring region 40a formed in an approximately L-shape in an xy plan view along a peripheral edge part of the transparent display device 100 is to be hidden by some kind of means.

The flexible wiring board 60 is a band-like opaque power feeder for feeding power to the display region 101. Since the flexible wiring board 60 is opaque, the flexible wiring board 60 is connected to an end part of the wiring 40 formed in an edge part of the transparent insulating substrate 10b. In the example shown in FIG. 1 and FIG. 2, the flexible wiring board 60 is connected to an end part of the wiring 40 in the opaque wiring region 40a formed in an end part on a side of the negative y-axis direction of the transparent insulating substrate 10b. The flexible wiring board 60 is to be also hidden by some kind of means, for example, in a similar manner to the opaque wiring region 40a.

As shown in FIG. 1 and FIG. 2, end parts of the transparent insulating substrate 10a and 10b overlap with each other. In the overlapping portion of the transparent insulating substrates 10a and 10b, one end of the wiring (the first wiring) 40 formed on the transparent insulating substrate 10a and one end of the wiring (the second wiring) 40 formed on the transparent insulating substrate 10b are electrically connected to each other. In addition, in an edge part of the transparent insulating substrate 10b, another end of the wiring 40 formed on the transparent insulating substrate 10b is connected to the flexible wiring board 60. According to such a configuration, power can be fed from the flexible wiring board 60 and an electronic element of the display region 101 can be driven. Note that the display region 101 does not overlap with the second wiring 40 formed on the transparent insulating substrate 10b. Therefore, since a decline in transmittance of the transparent display device 100 in the display region 101 can be suppressed, superior visibility of the rear-face side can be secured.

In addition, in the overlapping portion of the transparent insulating substrates 10a and 10b, at least one of the transparent insulating substrates 10a and 10b may have one or a plurality of cut-out parts. The cut-out parts improve adhesion between the transparent display device 100 and an interlayer to be described later and enable the transparent display device 100 to be securely held in a laminated glass.

In the example shown in FIG. 1 and FIG. 2, the end part on a side of the negative y-axis direction of the wiring 40 extended in the y-axis direction on the transparent insulating substrate 10a and the end part on a side of the positive y-axis direction of the wiring 40 extended in the y-axis direction on the transparent insulating substrate 10b oppose each other and are connected via a conductive joining layer 40b.

As the conductive joining layer 40b, for example, a conductive adhesive such as an anisotropic conductive film (ACF) or a solder can be used. Using a conductive adhesive, a solder, or the like enables a pad size to be reduced. In addition, burr created when providing a through-hole in the transparent insulating substrates does not occur and a favorable contact is obtained. As a result, a decline in yield can be suppressed.

In the example shown in FIG. 1, both of the transparent insulating substrates 10a and 10b have a rectangular planar shape. Due to end parts of the transparent insulating substrates 10a and 10b with equal widths overlapping and being connected with each other, the transparent insulating substrates 10a and 10b as a whole also have a rectangular planar shape. As shown in FIG. 1, a percentage of the end parts of the transparent insulating substrates 10a and 10b overlapping with each other is, for example, in terms of an area of the transparent insulating substrate 10a, 20% or lower, preferably 10% or lower, and more preferably 5% or lower.

In addition, two alignment marks AM for positioning are respectively provided in the transparent insulating substrates 10a and 10b. While a shape and the number of the alignment marks AM are not limited whatsoever, in the example shown in FIG. 1, a mark with a square shape is provided on one of the transparent insulating substrates 10a and 10b and a mark with a cross shape is provided on the other transparent insulating substrate. There may be one alignment mark AM or three or more alignment marks AM.

With previous transparent display devices, since all of the display region 101 and all of the wiring 40 were formed on one transparent insulating substrate, there was a problem of an increase in size and a decline in yield of the transparent display devices. For example, when a defect occurs in a non-display region even though a defect does not occur in the display region 101, a determination of a defect is made as a whole. In addition, when a defect occurs in the display region 101 even though a defect does not occur in the non-display region, a determination of a defect is made as a whole.

By comparison, in the transparent display device according to the present embodiment, the transparent insulating substrate is divided into the transparent insulating substrate 10a which includes the display region 101 and the transparent insulating substrate 10b which does not include the display region 101. Therefore, a defect in the transparent insulating substrate 10a which includes the display region 101 and a defect in the transparent insulating substrate 10b which does not include the display region 101 can be separated from each other and yield as a whole improves.

In addition, when a defect occurs in one of the transparent insulating substrates 10a and 10b being connected to each other, the one transparent insulating substrate can be readily replaced.

Furthermore, when designing a transparent display device 100 with a different size, for example, only a design of the transparent insulating substrate 10b can be changed without changing a design of the transparent insulating substrate 10a which includes the display region 101. In other words, by standardizing the transparent insulating substrate 10a, designing can be simplified and, at the same time, productivity in production also improves.

Note that in the example shown in FIG. 1, the opaque wiring region 40a is formed by being divided into the transparent insulating substrates 10a and 10b. However, for example, the transparent insulating substrate may be divided into the rectangular transparent insulating substrate 10a which includes the entire display region 101 and the transparent insulating substrate 10b shaped like the letter “L” in an xy plan view which includes the entire opaque wiring region 40a. Other modified examples will be described later.

### <Detailed Configuration of Display Region 101>

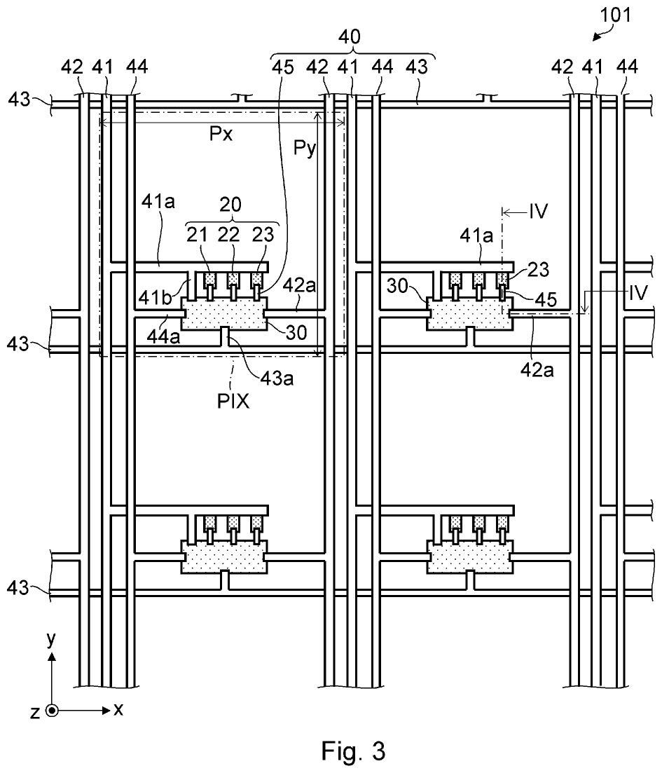

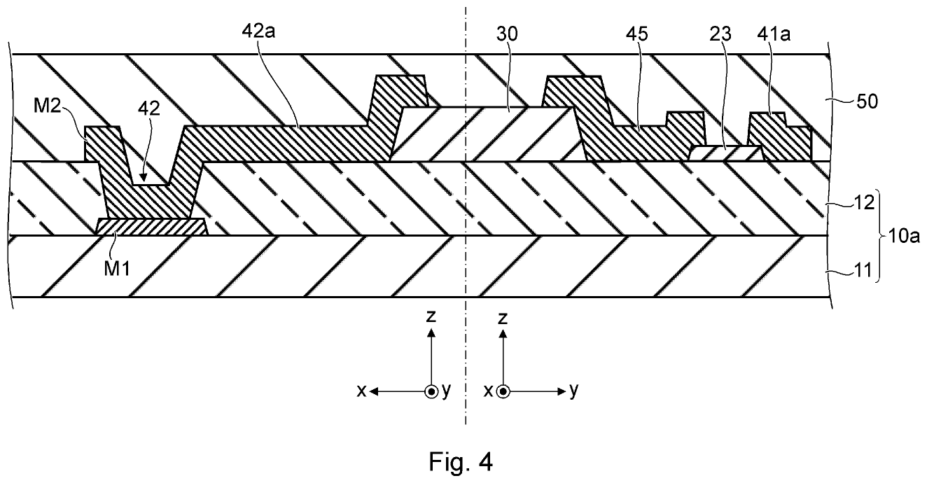

Next, a detailed configuration of the display region 101 in the transparent display device 100 according to the first embodiment will be explained with reference to FIG. 3 and FIG. 4. FIG. 3 is a schematic partial plan view showing an example of the display region 101. FIG. 4 is a sectional view taken along a cut line IV-IV in FIG. 3.

As described with reference to FIG. 1 and FIG. 2, the display region 101 is formed in the transparent insulating substrate 10a. As shown in FIG. 3 and FIG. 4, in the display region 101, a light-emitting part 20, an IC (integrated circuit) chip 30, a wiring 40, and a protective layer 50 are formed on the transparent insulating substrate 10a. As shown in FIG. 3, the display region 101 is constituted of a plurality of pixels PIX arranged in a row direction (x-axis direction) and a column direction (y-axis direction). FIG. 3 shows a part of the display region 101 and shows a total of four pixels constituted of two pixels respectively in the row direction and the column direction. In this case, one pixel PIX is shown enclosed by a dashed-dotted line. In addition, in FIG. 3, the transparent insulating substrate 10a and the protective layer 50 shown in FIG. 4 are omitted. Furthermore, although FIG. 3 is a plan view, the light-emitting part 20 and the IC chip 30 are displayed by dots in order to facilitate understanding.

### <Planar Arrangement of Light-Emitting Part 20, IC Chip 30, and Wiring 40>

First, a planar arrangement of the light-emitting part 20, the IC chip 30, and the wiring 40 will be described with reference to FIG. 3.

As shown in FIG. 3, the pixel PIX enclosed by a dashed-dotted line is arranged in a matrix pattern at a pixel pitch Px in the row direction (x-axis direction) and at a pixel pitch Py in the column direction (y-axis direction). In this case, as shown in FIG. 3, each pixel PIX includes the light-emitting part 20 and the IC chip 30. In other words, the light-emitting part 20 and the IC chip 30 are arranged in a matrix pattern at the pixel pitch Px in the row direction (x-axis direction) and at the pixel pitch Py in the column direction (y-axis direction).

Note that an arrangement format of the pixel PIX or, in other words, the light-emitting part 20 is not limited to a matrix pattern as long as the pixel PIX or the light-emitting part 20 is arranged at a predetermined pixel pitch in a predetermined direction.

As shown in FIG. 3, the light-emitting part 20 in each pixel PIX includes at least one LED element.

In the example shown in FIG. 3, each light-emitting part 20 includes a red-colored LED element 21, a green-colored LED element 22, and a blue-colored LED element 23. The LED elements 21 to 23 correspond to sub-pixels which constitute a single pixel. In this manner, since each light-emitting part 20 has the LED elements 21 to 23 which emit light in the colors of red, green, and blue being the three primary colors of light, the transparent display device according to the present embodiment can display a full-color image.

Note that each light-emitting part 20 may include two or more LED elements of a same color. Accordingly, a dynamics range of an image can be expanded.

The LED elements 21 to 23 are so-called micro LED elements with a minute size. Specifically, a width (a length in the x-axis direction) and a length (a length in the y-axis direction) of the LED element 21 on the transparent insulating substrate 10a are, respectively, for example, 100 μm or less, preferably 50 μm or less, and more preferably 20 μm or less. A similar description applies to the LED elements 22 and 23. Due to various manufacturing conditions and the like, a lower limit of the width and the length of the LED elements is, for example, 3 μm or more.

Note that while dimensions or, in other words, the widths and the lengths of the LED elements 21 to 23 in FIG. 3 are the same, the widths and the lengths may differ from one another.

In addition, an area occupied by each of the LED elements 21 to 23 on the transparent insulating substrate 10a is, for example, 10,000 μm² or less, preferably 3,000 μm² or less, and more preferably 500 μm² or less. Due to various manufacturing conditions and the like, a lower limit of the area occupied by one LED element is, for example, 10 μm² or more. In the present specification, an area occupied by a constituent member such as an LED element or a wiring indicates an area in an xy plan view in FIG. 3.

Note that while a shape of the LED elements 21 to 23 shown in FIG. 3 is a rectangular shape (including a square shape), the shape of the LED elements 21 to 23 is not particularly limited.

In this case, since the LED elements 21 to 23 have, for example, a mirror structure for extracting light to a visually-recognized side in an efficient manner, transmittance of the LED elements 21 to 23 is low at around 10% or lower, for example. However, in the transparent display device according to the present embodiment, as described earlier, the LED elements 21 to 23 with a minute size of which an area is 10,000 μm² or less are used. Therefore, for example, even when the transparent display device is observed from a short distance of around several 10 cm to 2 m, the LED elements 21 to 23 are hardly visually recognizable. In addition, a region with low transmittance in the display region 101 is narrow and superior visibility of the rear-face side can be secured. Furthermore, a degree of freedom of an arrangement of the wiring 40 and the like is also high.

Note that “a region with low transmittance in the display region 101” is, for example, a region of which transmittance is 20% or lower. A similar description applies hereinafter.

In addition, since LED elements 21 to 23 with a minute size are used, the LED elements are less susceptible to damage even when the transparent display device is bent. Therefore, the transparent display device according to the present embodiment can be used by mounting the transparent display device to a curved transparent plate such as a window glass for an automobile or sealing the transparent display device between two curved transparent plates. In this case, using a material with flexibility as the transparent insulating substrate 10a enables the transparent display device according to the present embodiment to be curved.

Although not particularly limited, the LED elements 21 to 23 are made of inorganic materials. For example, the red-colored LED element 21 is made of AlGaAs, GaAsP, GaP, or the like. For example, the green-colored LED element 22 is made of InGaN, GaN, AlGaN, GaP, AlGaInP, ZnSe, or the like. For example, the blue-colored LED element 23 is made of InGaN, GaN, AlGaN, ZnSe, or the like.

Luminous efficiency or, in other words, energy conversion efficiency of the LED elements 21 to 23 is, for example, 1% or higher, preferably 5% or higher, and more preferably 15% or higher. When the luminous efficiency of the LED elements 21 to 23 is 1% or higher, sufficient brightness is obtained even with the LED elements 21 to 23 with minute sizes as described above and the LED elements 21 to 23 can be used as a display device even during the day. In addition, when the luminous efficiency of the LED elements is 15% or higher, heat generation is suppressed and the LED elements can be readily sealed inside a laminated glass using a resin adhesion layer.

The pixel pitches Px and Py are, respectively, for example, 100 μm to 3,000 μm, preferably 180 μm to 1,000 μm, and more preferably 250 μm to 400 μm. Setting the pixel pitches Px and Py to the range described above enables high transparency to be realized while securing sufficient display capability. In addition, a diffraction phenomenon which may occur due to light from the rear-face side of the transparent display device can be suppressed.

Furthermore, a pixel density in the display region 101 of the transparent display device according to the present embodiment is, for example, 10 ppi or higher, preferably 30 ppi or higher, and more preferably 60 ppi or higher.

In addition, an area of one pixel PIX which is expressed as Px×Py is, for example, 1×10⁴ μm² to 9×10⁶ μm², preferably 3×10⁴ μm² to 1×10⁶ μm², and more preferably 6×10⁴ μm² to 2×10⁵ μm². Setting the area of one pixel to 1×10⁴ μm² to 9×10⁶ μm² enables transparency of the display device to be improved while securing suitable display capability. The area of one pixel may be appropriately selected based on a size, a usage, a visual recognition distance, or the like of the display region 101.

A percentage of the area occupied by the LED elements 21 to 23 with respect to the area of one pixel is, for example, 30% or less, preferably 10% or less, more preferably 5% or less, and even more preferably 1% or less. Setting the percentage of the area occupied by the LED elements 21 to 23 with respect to the area of one pixel to 30% or less improves transparency and visibility of the rear-face side.

In FIG. 3, while the three LED elements 21 to 23 are arranged in a single row in the positive x-axis direction in this order in each pixel, the arrangement of the LED elements 21 to 23 is not limited thereto. For example, the arrangement order of the three LED elements 21 to 23 may be changed. In addition, the three LED elements 21 to 23 may be arranged in the y-axis direction. Alternatively, the three LED elements 21 to 23 may be arranged at vertices of a triangle.

Furthermore, as shown in FIG. 3, when each light-emitting part 20 includes a plurality of LED elements 21 to 23, intervals among the LED elements 21 to 23 in the light-emitting part 20 is, for example, 100 μm or less and, preferably, 10 μm or less. Alternatively, the LED elements 21 to 23 may be arranged in contact with each other. Accordingly, a first power supply branch line 41a can be more readily standardized and a numerical aperture can be improved.

While an arrangement order, an arrangement direction, and the like of the plurality of LED elements in each light-emitting part 20 are the same in the example shown in FIG. 3, the arrangement order, the arrangement direction, and the like may differ among light-emitting parts 20. In addition, when each light-emitting part 20 includes three LED elements which emit light with different wavelengths, the LED elements may be arranged lined up in the x-axis direction or the y-axis direction in a part of the light-emitting parts 20 while the LED elements of the respective colors may be arranged at vertices of a triangle in other light-emitting parts 20.

In the example shown in FIG. 3, the IC chip 30 is arranged in each pixel PIX and drives the light-emitting part 20. Specifically, the IC chip 30 is connected to each of the LED elements 21 to 23 via a drive line 45 and can individually drive the LED elements 21 to 23. For example, the IC chip 30 is a hybrid IC including an analog region and a logic region. For example, the analog region includes an electrical current control circuit and a transformer circuit.

Alternatively, the IC chip 30 may be arranged for every plurality of pixels and each IC chip 30 may drive the plurality of pixels to which the IC chip 30 is connected. For example, by arranging one IC chip 30 for every four pixels, the number of IC chips 30 can be reduced to ¼ as compared to the example shown in FIG. 3 and an area occupied by the IC chips 30 can be reduced. In addition, the IC chips 30 are not essential.

An area per one IC chip 30 is, for example, 100,000 μm² or less, preferably 10,000 μm² or less, and more preferably 5,000 μm² or less. While a transmittance of the IC chip 30 is low at around 20% or less, using the IC chip 30 with the size described above narrows a region with low transmittance in the display region 101 and improves visibility of the rear-face side.

As shown in FIG. 3, the wiring 40 has a plurality of each of a power supply line 41, a ground line 42, a row data line 43, a column data line 44, and the drive line 45.

In the example shown in FIG. 3, the power supply line 41, the ground line 42, and the column data line 44 are extended in the y-axis direction. On the other hand, the row data line 43 is extended in the x-axis direction.

In addition, in each pixel PIX, the power supply line 41 and the column data line 44 are provided more toward a side of a negative x-axis direction than the light-emitting part 20 and the IC chip 30 and the ground line 42 is provided more toward a side of the positive x-axis direction than the light-emitting part 20 and the IC chip 30. In this case, the power supply line 41 is provided more toward the side of the negative x-axis direction than the column data line 44. In addition, in each pixel PIX, the row data line 43 is provided more toward a side of the negative y-axis direction than the light-emitting part 20 and the IC chip 30.

Furthermore, while details will be provided later, as shown in FIG. 3, the power supply line 41 includes the first power supply branch line 41a and a second power supply branch line 41b. The ground line 42 includes a ground branch line 42a. The row data line 43 includes a row data branch line 43a. The column data line 44 includes a column data branch line 44a. The respective branch lines are included in the wiring 40.

As shown in FIG. 3, each power supply line 41 extended in the y-axis direction is connected to the light-emitting part 20 and the IC chip 30 of each pixel PIX arranged in the y-axis direction. More specifically, in each pixel PIX, on the side of the positive x-axis direction of the power supply line 41, the LED elements 21 to 23 are arranged in the positive x-axis direction in this order. Therefore, the first power supply branch line 41a which branches in the positive x-axis direction from the power supply line 41 is connected to end parts on a side of the positive y-axis direction of the LED elements 21 to 23.

In addition, in each pixel PIX, the IC chip 30 is provided more toward a side of the negative y-axis direction than the LED elements 21 to 23. Therefore, between the LED element 21 and the column data line 44, the second power supply branch line 41b having been branched in the negative y-axis direction from the first power supply branch line 41a is linearly extended and connected to a side in the negative x-axis direction of the end part on a side of the positive y-axis direction of the IC chip 30.

As shown in FIG. 3, each ground line 42 extended in the y-axis direction is connected to the IC chip 30 of each pixel PIX arranged in the y-axis direction. Specifically, the ground branch line 42a having been branched in the negative x-axis direction from the ground line 42 is linearly extended and connected to an end part on a side of the positive x-axis direction of the IC chip 30.

In this case, the ground line 42 is connected to the LED elements 21 to 23 via the ground branch line 42a, the IC chip 30, and the drive line 45.

As shown in FIG. 3, each row data line 43 extended in the x-axis direction is connected to the IC chip 30 of each pixel PIX arranged in the x-axis direction (the row direction). Specifically, the row data branch line 43a having been branched in the positive y-axis direction from the row data line 43 is linearly extended and connected to an end part on a side of the negative y-axis direction of the IC chip 30.

In this case, the row data line 43 is connected to the LED elements 21 to 23 via the row data branch line 43a, the IC chip 30, and the drive line 45.

As shown in FIG. 3, each column data line 44 extended in the y-axis direction is connected to the IC chip 30 of each pixel PIX arranged in the y-axis direction (the column direction). Specifically, the column data branch line 44a having been branched in the positive x-axis direction from the column data line 44 is linearly extended and connected to an end part on a side of the negative x-axis direction of the IC chip 30.

In this case, the column data line 44 is connected to the LED elements 21 to 23 via the column data branch line 44a, the IC chip 30, and the drive line 45.

The drive line 45 connects the LED elements 21 to 23 and the IC chip 30 to each other in each pixel PIX. Specifically, in each pixel PIX, three drive lines 45 are extended in the y-axis direction, and each drive line 45 connects end parts on a side of the negative y-axis direction of the LED elements 21 to 23 and an end part on a side of the positive y-axis direction of the IC chip 30 to each other.

Note that the arrangements of the power supply line 41, the ground line 42, the row data line 43, the column data line 44, branch lines thereof, and the drive line 45 shown in FIG. 3 are merely examples and can be changed as appropriate. For example, at least one of the power supply line 41 and the ground line 42 may be extended in the x-axis direction instead of the y-axis direction. In addition, a configuration in which the power supply line 41 and the column data line 44 are interchanged may be adopted.

Furthermore, a configuration in which the entire configuration shown in FIG. 3 is vertically inverted, horizontally inverted or the like may be adopted.

Moreover, the row data line 43, the column data line 44, branch lines thereof, and the drive line 45 are not essential.

For example, the wiring 40 is made of a metal such as copper (Cu), aluminum (Al), silver (Ag), or gold (Au). Among these metals, a metal containing copper or aluminum as a main component is preferable due to low resistivity and from a cost perspective. In addition, the wiring 40 may be coated with a material such as titanium (Ti), molybdenum (Mo), copper oxide, or carbon for the purpose of reducing reflectance. Furthermore, irregularities may be formed on a surface of the coated material.

All of the widths of the wiring 40 in the display region 101 shown in FIG. 3 are, for example, 1 μm to 100 μm and, preferably, 3 μm to 20 μm. When the width of the wiring 40 is 100 μm or less, for example, even when the transparent display device is observed from a short distance of around several 10 cm to 2 m, the wiring 40 is hardly visually recognizable and superior visibility of the rear-face side can be secured. On the other hand, in a case of a range of thickness to be described later, when the width of the wiring 40 is 1 μm or more, an excessive rise in resistance of the wiring 40 can be suppressed and a voltage drop or a decline in signal strength can be suppressed. In addition, a decline in thermal conductivity due to the wiring 40 can also be suppressed.

When the wiring 40 is mainly extended in the x-axis direction and the y-axis direction as shown in FIG. 3, a cross diffraction pattern extending in the x-axis direction and the y-axis direction may be generated by light radiated from outside of the transparent display device and may cause a decline in visibility of the rear-face side of the transparent display device. Reducing the width of each wiring enables the diffraction to be suppressed and the visibility of the rear-face side to be further improved. From the perspective of suppressing the diffraction, the width of the wiring 40 is 50 μm or less, preferably 10 μm or less, and more preferably 5 μm or less.

Electrical resistivity of the wiring 40 is, for example, 1.0×10⁻⁶ Ωm or less and preferably 2.0×10⁻⁸ Ωm or less. In addition, thermal conductivity of the wiring 40 is, for example, 150 W/(m·K) to 5,500 W/(m·K) and preferably 350 W/(m·K) to 450 W/(m·K).

Intervals between adjacent wirings 40 in the display region 101 shown in FIG. 3 are, for example, 3 μm to 100 μm and, preferably, 5 μm to 30 μm. The presence of a region where the wiring 40 is closely packed may inhibit visual recognition of the rear-face side. Setting the intervals between adjacent wirings 40 to 3 μm or more enables such inhibition of visual recognition to be suppressed. On the other hand, setting the intervals between adjacent wirings 40 to 100 μm or less enables sufficient display capability to be secured.

Note that when intervals between wirings 40 are not constant such as when the wirings 40 are curved, the intervals between the adjacent wirings 40 described above refer to a minimum value of the intervals.

A percentage of the area occupied by the wiring 40 with respect to the area of one pixel is, for example, 30% or less, preferably 10% or less, more preferably 5% or less, and even more preferably 3% or less. The transmittance of the wiring 40 is low at, for example, 20% or less or 10% or less. However, by setting the area occupied by the wiring 40 in one pixel to 30% or less, a region with low transmittance in the display region 101 narrows and the visibility of the rear-face side is improved.

Furthermore, a sum of areas occupied by the light-emitting part 20, the IC chip 30, and the wiring 40 with respect to the area of one pixel is, for example, 30% or less, preferably 20% or less, and more preferably 10% or less.

<Configuration of Cross Section of Display Region 101 (Transparent Insulating Substrate 10a)>

Next, a configuration of a cross section of the display region 101 formed on the transparent insulating substrate 10a in the transparent display device according to the present embodiment will be explained with reference to FIG. 4.

The transparent insulating substrate 10a is made of a transparent material with insulation properties. In the example shown in FIG. 4, the transparent insulating substrate 10a has a two-layer structure including a main substrate 11 and an adhesive layer 12.

As will be described in detail later, the main substrate 11 is made of, for example, a transparent resin.

The adhesive layer 12 is made of, for example, a transparent resin adhesive such as an epoxy-based adhesive, an acrylic adhesive, a silicone-based adhesive, an olefin-based adhesive, a polyimide-based adhesive, or a novolac-based adhesive.

Alternatively, the main substrate 11 may be a thin glass plate with a thickness of, for example, 200 μm or less and, preferably, 100 μm or less. In addition, the adhesive layer 12 is not essential.

Examples of the transparent resin which constitutes the main substrate 11 include: a polyester-based resin such as polyethylene terephthalate (PET) or polyethylene naphthalate (PEN); an olefin-based resin such as a cycloolefin polymer (COP) or a cycloolefin copolymer (COC); a cellulose-based resin such as cellulose, acetyl cellulose, or triacetyl cellulose (TAC); an imide-based resin such as polyimide (PI); an amide-based resin such as polyamide (PA); an amide-imide-based resin such as polyamide-imide (PAI); a carbonate-based resin such as polycarbonate (PC); a sulfone-based resin such as polyether sulfone (PES); a paraxylene-based resin such as poly-paraxylene; a vinyl-based resin such as polyethylene (PE), polyvinyl chloride (PVC), polystyrene (PS), polyvinyl acetate (PVAc), polyvinyl alcohol (PVA), or polyvinyl butyral (PVB); an acrylic resin such as polymethylmethacrylate (PMMA); an ethylene-vinyl acetate copolymer resin (EVA); a urethane-based resin such as thermoplastic polyurethane (TPU); and an epoxy-based resin.

Among the materials which may be used in the main substrate 11 described above, polyethylene naphthalate or polyimide is preferable from the perspective of improving heat resistance. In addition, a cycloolefin polymer, a cycloolefin copolymer, polyvinyl butyral, or the like is preferable in terms of a low birefringence index and an ability to reduce distortion or blurring of an image viewed through the transparent insulating substrate.

The materials described above may be used alone or two or more may be used in combination. Furthermore, the main substrate 11 may be constructed by laminating flat plates made of different materials.

A thickness of the entire transparent insulating substrate 10a is, for example, 3 μm to 1,000 μm and, preferably, 5 μm to 200 μm. Internal transmittance of visible light of the transparent insulating substrate 10a is, for example, 50% or higher, preferably 70% or higher, and more preferably 90% or higher.

In addition, the transparent insulating substrate 10a may have flexibility and, accordingly, for example, the transparent display device can be used by mounting the transparent display device to a curved transparent plate or by sandwiching the transparent display device between two curved transparent plates. Furthermore, the transparent insulating substrate 10a may be made of a material which contracts when heated to 100° C. or higher.

As shown in FIG. 4, the LED elements 21 to 23 and the IC chip 30 are provided on the transparent insulating substrate 10a or, in other words, the adhesive layer 12 and connected to the wiring 40 which is arranged on the transparent insulating substrate 10a. In the example shown in FIG. 4, the wiring is constituted of a first metal layer M1 formed on the main substrate 11 and a second metal layer M2 formed on the adhesive layer 12.

A thickness of the wiring 40 or, in other words, a sum of a thickness of the first metal layer M1 and a thickness of the second metal layer M2 is, for example, 0.1 μm to 10 μm and, preferably, 0.5 μm to 5 μm. The thickness of the first metal layer M1 is, for example, around 0.5 μm, and the thickness of the second metal layer M2 is, for example, around 3 μm.

Specifically, as shown in FIG. 4, since an amount of an electrical current in the ground line 42 extended in the y-axis direction is large, the ground line 42 has a two-layer structure including the first metal layer M1 and the second metal layer M2. In other words, in a location where the ground line 42 is provided, the adhesive layer 12 is removed and the second metal layer M2 is formed on top of the first metal layer M1. Although not shown in FIG. 4, the power supply line 41, the row data line 43, and the column data line 44 shown in FIG. 3 similarly have two-layer structures including the first metal layer M1 and the second metal layer M2.

In this case, as shown in FIG. 3, the power supply line 41, the ground line 42, and the column data line 44 which are extended in the y-axis direction 10 intersect with the row data line 43 which is extended in the x-axis direction. Although not illustrated in FIG. 4, in the intersections, the row data line 43 is solely constituted of the first metal layer M1 and the power supply line 41, the ground line 42, and the column data line 44 are solely constituted of the second metal layer M2. In addition, in the intersections, the adhesive layer 12 is provided between the first metal layer M1 and the second metal layer M2 and the first metal layer M1 and the second metal layer M2 are insulated from each other.

In a similar manner, in the intersections of the column data line 44 and the first power supply branch line 41a, the first power supply branch line 41a is solely constituted of the first metal layer M1 and the column data line 44 is solely constituted of the second metal layer M2.

Furthermore, in the example shown in FIG. 4, the ground branch line 42a, the drive line 45, and the first power supply branch line 41a are solely constituted of the second metal layer M2 and formed so as to cover end parts of the LED elements 21 to 23 and the IC chip 30. Although not illustrated in FIG. 4, the second power supply branch line 41b, the row data branch line 43a, and the column data branch line 44a are similarly solely constituted of the second metal layer M2.

Note that as described above, the first power supply branch line 41a is solely constituted of the first metal layer M1 in intersections with the column data line 44 but solely constituted of the second metal layer M2 in other locations. Alternatively, a metal pad made of copper, silver, gold, or the like may be arranged on the wiring 40 formed on the transparent insulating substrate 10a and at least one of the LED elements 21 to 23 and the IC chip 30 may be arranged on the metal pad.

The protective layer 50 is made of a transparent resin formed on approximately an entire surface of the transparent insulating substrate 10a so as to cover and protect the light-emitting part 20, the IC chip 30, and the wiring 40. For example, an “approximately an entire surface” in this case refers to an entire surface other than a portion to be electrically connected to the transparent insulating substrate 10b and the flexible wiring board 60 among the surface of the transparent insulating substrate 10a.

A thickness of the protective layer 50 is, for example, 3 μm to 1,000 μm and, preferably, 5 μm to 200 μm. The thickness of the protective layer 50 need not be uniform as long as the thickness is within this range.

A modulus of elasticity of the protective layer 50 is, for example, 10 GPa or lower. A lower modulus of elasticity enables an impact upon separation to be absorbed and suppresses damage to the protective layer 50.

Internal transmittance of visible light of the protective layer 50 is, for example, 50% or higher, preferably 70% or higher, and more preferably 90% or higher.

Note that the protective layer 50 is not essential.

Examples of the transparent resin which constitutes the protective layer 50 include: a vinyl-based resin such as polyethylene (PE), polyvinyl chloride (PVC), polystyrene (PS), polyvinyl acetate (PVAc), polyvinyl alcohol (PVA), or polyvinyl butyral (PVB); an olefin-based resin such as a cycloolefin polymer (COP) or a cycloolefin copolymer (COC); a urethane-based resin such as thermoplastic polyurethane (TPU); a polyester-based region such as polyethylene terephthalate (PET) or polyethylene naphthalate (PEN); an acrylic resin such as polymethylmethacrylate (PMMA); and a thermoplastic resin such as ethylene-vinyl acetate copolymer resin (EVA). In addition, the transparent resin adhesive which constitutes the adhesive layer 12 can also be used as the transparent resin which constitutes the protective layer 50. Note that the protective layer 50 may be constituted of a single type of transparent resin or a plurality of types of transparent resin.

<Configuration of Cross Section of Non-Display Region (Transparent Insulating Substrate 10b)>

Next, a configuration of a cross section of the non-display region formed on the transparent insulating substrate 10b in the transparent display device according to the present embodiment will be explained with reference to FIG. 2.

As shown in FIG. 2, the display region 101 is not formed but the wiring 40 is formed on the transparent insulating substrate 10b. For example, the wiring 40 solely constituted of the first metal layer M1 described above is formed on the transparent insulating substrate 10b solely constituted of the main substrate 11 described above. In addition, in a similar manner to the display region 101, the protective layer 50 which covers the wiring 40 may be formed on the transparent insulating substrate 10b. As a material of the main substrate 11 which constitutes the transparent insulating substrate 10b, a material similar to that of the main substrate 11 which constitutes the transparent insulating substrate 10a can be used. The material of the main substrate 11 which constitutes the transparent insulating substrate 10b may differ from the material of the main substrate 11 which constitutes the transparent insulating substrate 10a.

### <Manufacturing Method of Transparent Display Device>

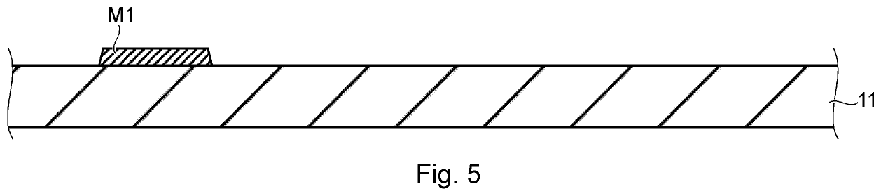

Next, an example of a manufacturing method of the transparent display device according to the first embodiment will be explained with reference to FIG. 2 and FIG. 5 to FIG. 12. FIG. 5 to FIG. 12 are sectional views showing an example of the manufacturing method of the transparent display device according to the first embodiment. FIG. 5 to FIG. 12 are sectional views corresponding to FIG. 4 and show how the display region 101 is formed on the transparent insulating substrate 10a.

First, as shown in FIG. 5, after forming the first metal layer M1 on approximately an entire surface of the main substrate 11, the first metal layer M1 is patterned by photolithography and a lower-layer wiring is formed. Specifically, the lower-layer wiring is formed by the first metal layer M1 at positions where the power supply line 41, the ground line 42, the row data line 43, the column data line 44, and the like shown in FIG. 3 are to be formed.

Note that the lower-layer wiring is not formed in intersections of the power supply line 41, the ground line 42, and the column data line 44 with the row data line 43.

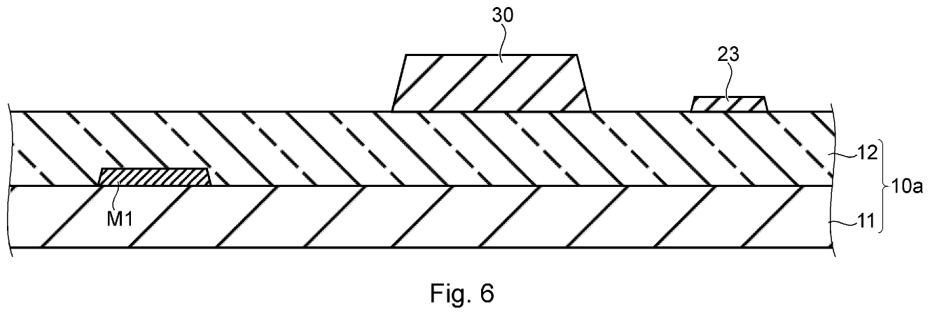

Next, as shown in FIG. 6, after forming the adhesive layer 12 on approximately the entire surface of the main substrate 11, the LED elements 21 to 23 and the IC chip 30 are mounted on the adhesive layer 12 (in other words, on the transparent insulating substrate 10a) having tackiness.

In this case, the LED elements 21 to 23 are obtained by growing a crystal on a wafer using a liquid phase growth method, an HVPE (hydride vapor phase epitaxy) method, a MOCVD (metal organic chemical vapor deposition) method, or the like and then performing patterning. The LED elements 21 to 23 having been patterned on the wafer are transferred onto the transparent insulating substrate 10a using, for example, a micro-transfer printing technique. In addition, regarding the IC chip 30, for example, the IC chip 30 having been patterned on a Si wafer is transferred onto the transparent insulating substrate 10a using a micro-transfer printing technique in a similar manner to the LED elements 21 to 23.

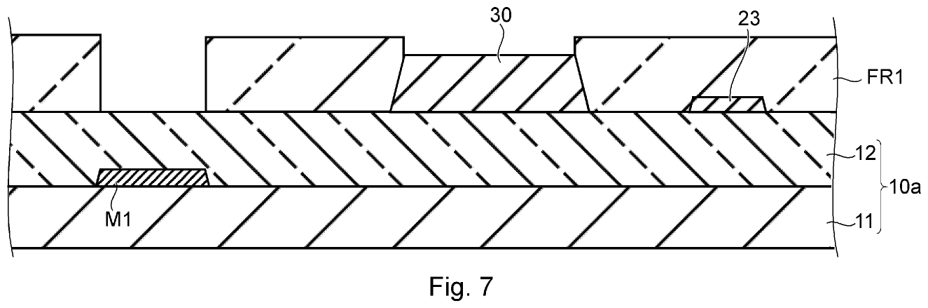

Next, as shown in FIG. 7, after forming a photoresist FR1 on approximately the entire surface of the transparent insulating substrate 10a which includes the main substrate 11 and the adhesive layer 12, the photoresist FR1 on the first metal layer M1 is removed by patterning. At this point, the photoresist FR1 in the intersections of the row data line 43 with the power supply line 41, the ground line 42, and the column data line 44 shown in FIG. 3 are not removed.

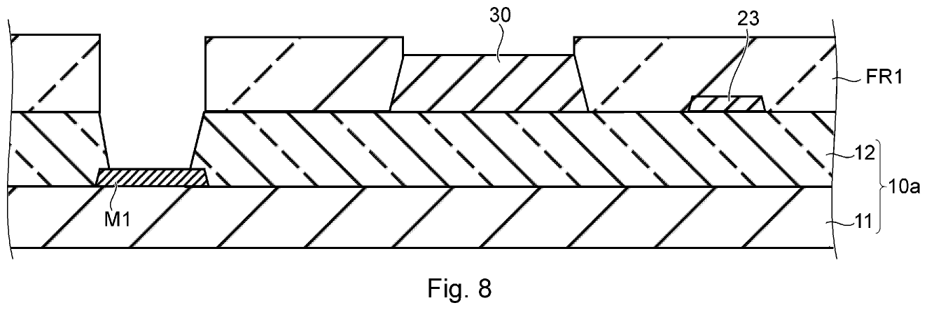

Next, as shown in FIG. 8, the adhesive layer 12 at locations where the photoresist FR1 has been removed is removed by dry etching to expose the first metal layer M1 or, in other words, the lower-layer wiring.

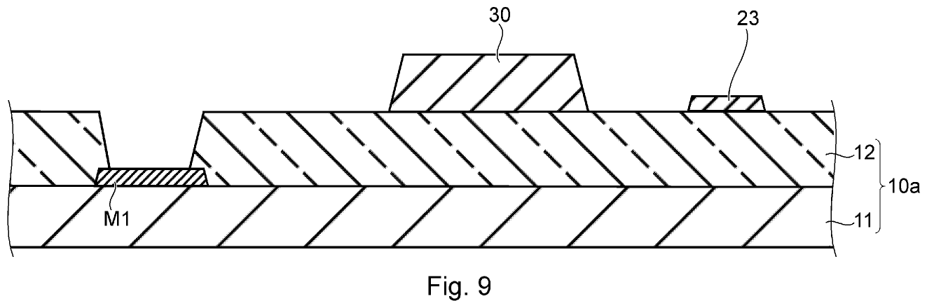

Next, as shown in FIG. 9, all of the photoresist FR1 on the transparent insulating substrate 10a is removed. Subsequently, a seed layer for plating (not illustrated) is formed on approximately the entire surface of the transparent insulating substrate 10a.

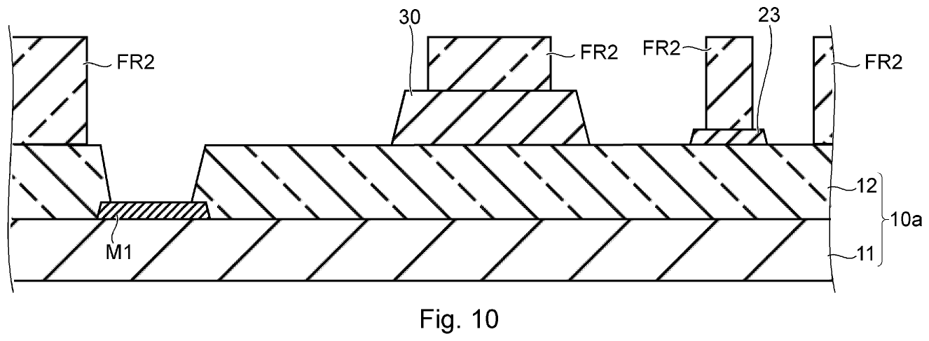

Next, as shown in FIG. 10, after forming a photoresist FR2 on approximately the entire surface of the transparent insulating substrate 10a, the photoresist FR2 in locations where an upper-layer wiring is to be formed is removed by patterning to expose the seed layer.

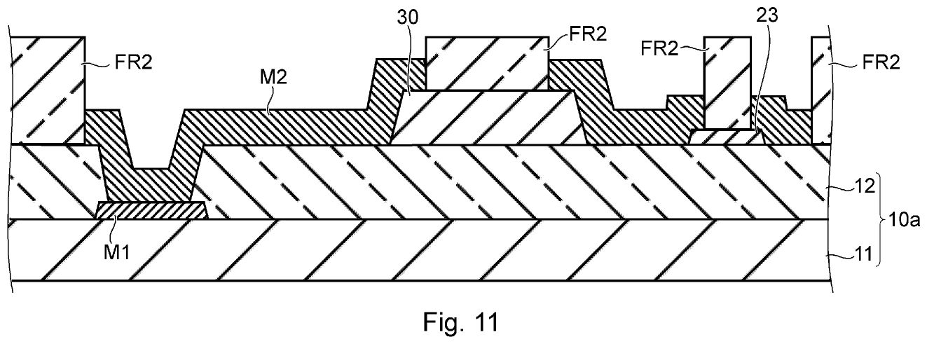

Next, as shown in FIG. 11, the second metal layer M2 is formed by plating on the locations where the photoresist FR2 has been removed or, in other words, on the seed layer. Accordingly, the upper-layer wiring is formed by the second metal layer M2.

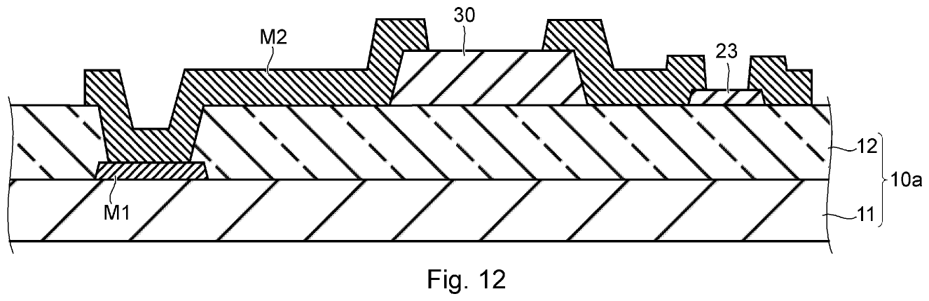

Next, as shown in FIG. 12, the photoresist FR2 is removed. Furthermore, the seed layer having been exposed by removing the photoresist FR2 is removed by etching.

Accordingly, the display region 101 is formed on the transparent insulating substrate 10a.

On the other hand, although not separately illustrated, the wiring 40 is formed on the transparent insulating substrate 10b as described above. For example, as shown in FIG. 5, the wiring 40 solely constituted of the first metal layer M1 described above is patterned on the transparent insulating substrate 10b solely constituted of the main substrate 11.

In addition, as shown in FIG. 2, one end of the wiring 40 formed on the transparent insulating substrate 10a and one end of the wiring formed on the transparent insulating substrate 10b are joined via the conductive joining layer 40b to be electrically connected to each other. Furthermore, in an edge part of the transparent insulating substrate 10b, another end of the wiring 40 is connected to the flexible wiring board 60.

Subsequently, the protective layer 50 may be formed on the transparent insulating substrates 10a and 10b.

Accordingly, the transparent display device 100 according to the present embodiment can be manufactured.

### Modified Examples of First Embodiment

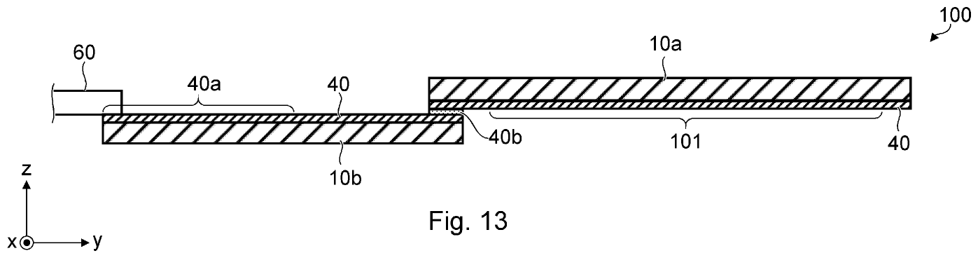

Next, transparent display devices according to modified examples of the first embodiment will be explained with reference to FIG. 13 to FIG. 16.

FIG. 13 to FIG. 16 are, respectively, schematic sectional views showing a transparent display device according to first to fourth modified examples of the first embodiment. In addition, FIG. 13 to FIG. 16 are diagrams corresponding to FIG. 2.

The transparent display device 100 according to the first modified example shown in FIG. 13 has a vertically-inverted configuration. In other words, the transparent insulating substrate 10a may be formed on top of the transparent insulating substrate 10b. In the transparent display device 100 according to the first modified example, the display region 101 does not overlap with the second wiring 40 formed on the transparent insulating substrate 10b. Therefore, the transparent display device 100 according to the first modified example can suppress a decline in transmittance in the display region 101 and provides superior visibility of the rear-face side. Note that a similar description applies to the transparent display devices 100 according to the second to fourth modified examples to be described later.

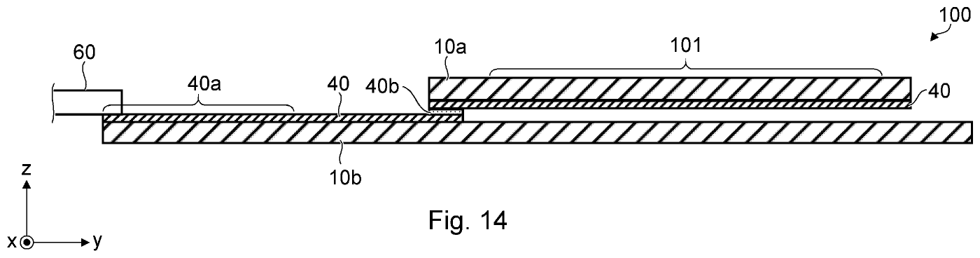

The transparent display device 100 according to the second modified example shown in FIG. 14 has a configuration in which the transparent insulating substrate 10b is extended over an entire lower side of the transparent insulating substrate 10a in the transparent display device 100 according to the first modified example shown in FIG. 13. In other words, an entirety of the transparent insulating substrate 10a (100% of the area of the transparent insulating substrate 10a) overlaps with the transparent insulating substrate 10b. Therefore, when sealing the transparent display device 100 inside a laminated glass as will be described later, a shape of the transparent insulating substrate 10a (in other words, the display region 101) can be stabilized as compared to the configurations shown in FIG. 2 and FIG. 13.

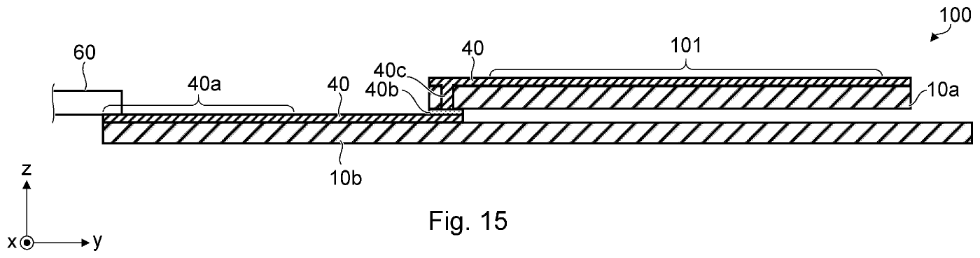

The transparent display device 100 according to the third modified example shown in FIG. 15 has a configuration in which only the transparent insulating substrate 10a is vertically inverted in the transparent display device 100 according to the second modified example shown in FIG. 14. In other words, the wiring 40 is formed on an upper surface of the transparent insulating substrate 10a. Therefore, the wiring 40 formed on the upper surface of the transparent insulating substrate 10a and the wiring 40 formed on an upper surface of the transparent insulating substrate 10b are connected via a via 40c which penetrates the transparent insulating substrate 10a.

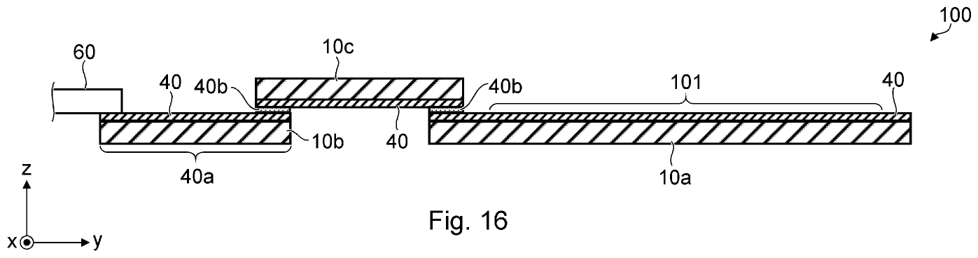

The transparent display device 100 according to the fourth modified example shown in FIG. 16 has a configuration in which the transparent insulating substrate 10a which includes the display region 101 and the transparent insulating substrate 10b connected to the flexible wiring board 60 are connected via a transparent insulating substrate (a third transparent insulating substrate) 10c. In this manner the transparent insulating substrate may be divided three ways or more. The transparent insulating substrate 10a and the transparent insulating substrate 10b do not overlap with each other and the wiring 40 is formed on both upper surfaces of the transparent insulating substrate 10a and the transparent insulating substrate 10b.

In the fourth modified example, the end part on a side of the negative y-axis direction of the wiring 40 extended in the y-axis direction on the transparent insulating substrate 10a and the end part on a side of the positive y-axis direction of the wiring 40 extended in the y-axis direction on the transparent insulating substrate 10c oppose each other and are connected via a conductive joining layer 40b. In a similar manner, the end part on a side of the positive y-axis direction of the wiring 40 in the opaque wiring region 40a formed on the transparent insulating substrate 10b and the end part on a side of the negative y-axis direction of the wiring 40 in the opaque wiring region 40a formed on the transparent insulating substrate 10c oppose each other and are connected via a conductive joining layer 40b.

In this case, the wiring 40 in the opaque wiring region 40a is formed but an LED element is not formed on the transparent insulating substrate 10b. Therefore, the wiring 40 can be readily formed on the transparent insulating substrate 10b using print-patterning instead of patterning due to photolithography.

Note that both the wiring 40 in the opaque wiring region 40a and the fine wiring 40 are formed on a lower surface of the transparent insulating substrate 10c.

### Second Embodiment

### <Configuration of Laminated Glass Including Transparent Display Device>

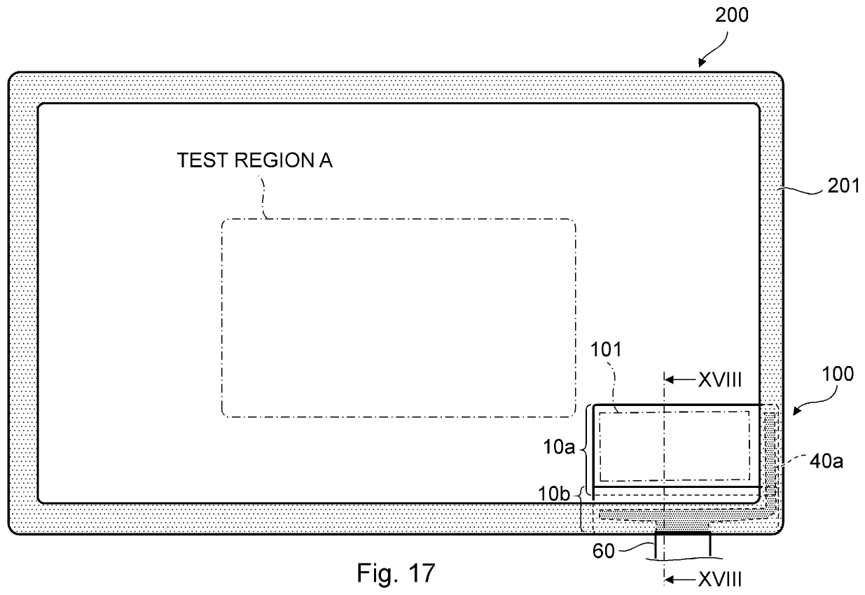

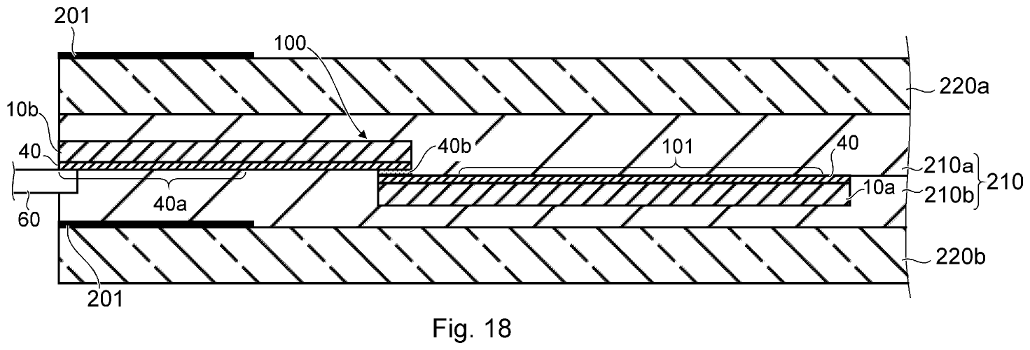

Next, a configuration of a laminated glass according to a second embodiment will be explained with reference to FIG. 17 and FIG. 18. FIG. 17 is a schematic plan view showing an example of the laminated glass according to the second embodiment. FIG. 18 is a sectional view taken along a cut line XVIII-XVIII in FIG. 17. Although a laminated glass 200 shown in FIG. 17 and FIG. 18 is used in a windshield among window glasses for an automobile, the laminated glass 200 is not particularly limited to a windshield. For example, the laminated glass according to the embodiment can be used as window glasses for vehicles including trains, ships, and airplanes or, in other words, vehicles in general. Besides the windshield, window glasses include a rear window glass, a side window glass, and a roof window glass.

As shown in FIG. 18, the laminated glass 200 is constructed by bonding together a pair of glass plates 220a and 220b arranged so as to oppose each other via an interlayer 210. In the laminated glass 200, the transparent display device 100 according to the first embodiment shown in FIG. 2 is sandwiched by interlayers 210a and 210b between the pair of glass plates 220a and 220b.

When the laminated glass 200 is mounted to a vehicle, for example, the glass plate 220a is arranged on a vehicle interior side (a visually recognized side) and the glass plate 220b is arranged on a vehicle exterior side (background side). In addition, the interlayer (the first interlayer) 210a and the interlayer (the second interlayer) 210b are integrated to constitute the interlayer 210.

As shown in FIG. 17 and FIG. 18, the transparent display device 100 is provided in an end part of the laminated glass 200 and the flexible wiring board 60 is extended from the glass plates 220a and 220b. Note that the transparent display device 100 may be arranged in plurality inside the laminated glass 200.

While the laminated glass 200 is planarly shown in FIG. 17, the laminated glass 200 may have a curved shape instead. The curved shape may be a single curved shape which is curved in one direction or a double curved shape which is curved in two perpendicular directions. When the laminated glass 200 is curved, a radius of curvature is preferably 1,000 mm to 10,000 mm. The radii of curvature of the glass plates 220a and 220b may be the same or may differ from each other. When the radii of curvature of the glass plates 220a and 220b differ from each other, the radius of curvature of the glass plate 220b is larger than the radius of curvature of the glass plate 220a.

In addition, while a planar shape of the laminated glass 200 shown in FIG. 17 is a rectangular shape, the planar shape is not limited to a rectangular shape and may be any shape including a trapezoidal shape, a shape of a parallelogram, or a triangular shape.

In the transparent display device 100 shown in FIG. 2, each of peripheral edges of the transparent insulating substrate 10a and 10b is installed so as not to overlap with predetermined test areas in the glass plates 220a and 220b. In this case, the predetermined test area refers to the “Test region A” as defined in Annex “Test regions for optical properties and light resistance tests of safety glass” of JIS Standard R3212:2015 (Test methods of safety glazing materials for road vehicles). This is because, when the peripheral edges of the transparent insulating substrates 10a and 10b overlap with the “Test region A”, for example, there is a risk that a field of view of a driver may be adversely affected by reflection, scattering or the like or the glass plates 220a and 220b may be prevented from passing tests related to transparent distortion and the like.

In this case, FIG. 17 schematically shows the “Test region A”.

Cases where the peripheral edge of the transparent insulating substrate 10a does not overlap with the “Test region A” include, in addition to a case where the transparent insulating substrate 10a shown in FIG. 17 does not overlap with the Test region A or, in other words, a case where the transparent insulating substrate 10a exists outside the Test region A, a case where the transparent insulating substrate 10a overlaps with and encompasses the entire Test region A. A similar description also applies to the transparent insulating substrate 10b.

Furthermore, as shown in FIG. 17, the laminated glass 200 is provided with a band-like shielding layer 201 on an entire peripheral edge thereof. Since the shielding layer 201 shields sunlight, deterioration due to ultraviolet light of an adhesive (for example, a resin such as urethane) for installing the laminated glass 200 to an automobile can be suppressed.

Note that although FIG. 17 is a plan view, the shielding layer 201 and the opaque wiring region 40a are displayed by dots in order to facilitate understanding.

In the example shown in FIG. 18, when the laminated glass 200 is mounted to a vehicle, the shielding layer 201 is formed on a vehicle interior-side surface of the glass plate 220a and a vehicle interior-side surface of the glass plate 220b.

Note that the shielding layer 201 may be formed on only one of the vehicle interior-side surface of the glass plate 220a and the vehicle interior-side surface of the glass plate 220b.

In this case, as shown in FIG. 17 and FIG. 18, the shielding layer 201 is formed so as to overlap with the flexible wiring board 60 and the opaque wiring region 40a. Therefore, the flexible wiring board 60 and the opaque wiring region 40a become less visually recognizable from the vehicle interior side and the vehicle exterior side and designability of the laminated glass 200 improves.

In addition, as shown in FIG. 17 and FIG. 18, a part of the peripheral edges of the transparent insulating substrates 10a and 10b of the transparent display device 100 overlaps with the shielding layer 201 and is less visually recognizable. For example, when a size of the transparent display device 100 is increased or the like, all of the peripheral edges of the transparent insulating substrates 10a and 10b may overlap with the shielding layer 201.

Furthermore, where the flexible wiring board 60 and the opaque wiring region 40a are provided, preferably, the flexible wiring board 60 and the opaque wiring region 40a are within 20 mm from an end part of the glass plate 220a or the glass plate 220b because the flexible wiring board 60 and the opaque wiring region 40a can be readily hidden by a body frame or interior materials of the vehicle and, more preferably, the flexible wiring board 60 and the opaque wiring region 40a are within 10 mm from the end part of the glass plate 220a or the glass plate 220b. In addition, when the laminated glass 200 is a door glass to be slidably installed in a vehicle, preferably, a portion where the opaque wiring region 40a is to be provided is within 15 mm from the end part of the glass plate 220a or the glass plate 220b because the opaque wiring region 40a can be readily hidden by a door sash and, more preferably, the opaque wiring region 40a is within 10 mm from the end part of the glass plate 220a or the glass plate 220b.

Although not particularly limited, for example, the shielding layer 201 can be formed by applying and baking a ceramic color paste including a fusible glass frit containing a pigment. For example, the shielding layer 201 may be formed by applying and drying an organic ink containing a pigment. Alternatively, the shielding layer 201 may be formed with a color film. While a color of the pigment and a color of the colored film may be any color as long as visible light can be blocked to such an extent that at least a portion which needs to be shielded can be shielded, a dark color is preferable and black is more preferable. In addition, the shielding layer 201 is preferably opaque.

The glass plates 220a and 220b and the interlayer 210 will now be described in detail.

The glass plates 220a and 220b may be made of either inorganic glass or organic glass. As the inorganic glass, for example, a soda-lime glass, an alumino-silicate glass, a borosilicate glass, an alkali-free glass, or a quartz glass is used without particular limitations. The glass plate 220b positioned on the vehicle exterior side is preferably an inorganic glass from the perspective of scratch resistance and preferably a soda-lime glass from the perspective of formability. In addition, a glass which absorbs ultraviolet light or infrared light may be used in the glass plates 220a and 220b and, furthermore, while the glass is preferably transparent, a glass plate which is colored without sacrificing transparency may also be used. When the glass plates 220a and 220b are a soda-lime glass, a clear glass or green glass and UV-blocking green glass containing a predetermined amount of an iron component or more can be suitably used.

The inorganic glass may be any of a non-tempered glass or a tempered glass. A non-tempered glass is obtained by forming molten glass into a plate shape and slow-cooling the glass. A tempered glass is obtained by forming a compression stress layer on a surface of the non-tempered glass.

The tempered glass may be any of a physically tempered glass such as a thermally tempered glass or a chemically strengthened glass. A physically tempered glass enables a glass surface to be tempered through an operation other than slow cooling such as quenching of a glass plate having been uniformly heated in bending and forming from a temperature near a softening point to create a compression stress layer on a glass surface due to a temperature difference between the glass surface and interior of the glass.

A chemically strengthened glass enables a glass surface to be tempered by, for example, causing a compression stress to be created on the glass surface by an ion exchange method or the like after bending and forming.

On the other hand, examples of a material of an organic glass include transparent resins such as polycarbonate, polymethyl methacrylate and other acrylic resins, polyvinyl chloride, and polystyrene.

A shape of the glass plates 220a and 220b is not particularly limited to a rectangular shape and may be various shapes or shapes processed in various curvatures. Gravity molding, press molding, roller molding, or the like is used to bend and form the glass plates 220a and 220b. While the molding method of the glass plates 220a and 220b is also not particularly limited, for example, a glass plate formed by a float process is preferable in the case of an inorganic glass.

When the laminated glass 200 is installed in a vehicle, a thinnest part of a thickness of the glass plate 220b positioned on a vehicle exterior side is preferably 1.5 mm to 3.0 mm or less. When the thickness of the glass plate 220b is 1.5 mm or more, strength such as stone chip resistance is sufficient, and when the thickness of the glass plate 220b is 3.0 mm or less, a mass of the laminated glass is prevented from becoming excessively large and is preferable in terms of fuel economy of the vehicle. The thinnest part of the thickness of the glass plate 220b is more preferably 1.5 to 2.8 mm and even more preferably 1.5 mm to 2.6 mm.

When the laminated glass 200 is installed in a vehicle, a thickness of the glass plate 220a positioned on a vehicle interior side is preferably 0.3 mm to 2.3 mm. Favorable handling ability is realized when the thickness of the glass plate 220a is 0.3 mm or more and a mass of the glass plate 220a is prevented from becoming excessively large when the thickness is 2.3 mm or less.

The thickness of each of the glass plates 220a and 220b may change depending on location when necessary instead of being a constant thickness. For example, when the laminated glass 200 is a windshield, each of the glass plates 220a and 220b may have a wedge shape of which a thickness increases from a lower side toward an upper side of the windshield in a state where the windshield is installed to the vehicle. In this case, when a film thickness of the interlayer 210 is constant, a total wedge angle of the glass plates 220a and 220b changes within a range of, for example, larger than 0 mrad and 1.0 mrad or less.

The laminated glass 200 may be provided with a functional coating such as a water-repellent coating, an ultraviolet light-blocking coating, or an infrared light-blocking coating or a coating having low reflection characteristics or low radiation characteristics on an outer side of the glass plates 220a and 220b. In addition, the laminated glass 200 may be provided with an ultraviolet light-blocking coating, an infrared light-blocking coating, a coating with low reflection characteristics, a visible light-absorbing coating, a colored coating, or the like on an inner side (a side in contact with the interlayer 210) of the glass plates 220a and 220b.

When the glass plates 220a and 220b are an inorganic glass, for example, the glass plates 220a and 220b are bent and formed after forming by a float process or the like and before adhesion by the interlayer 210. Bending and forming are performed by softening the glass by heating. A heating temperature of glass during bending and forming is around 550° C. to 700° C.

A thermoplastic resin is often used as the interlayer 210. Examples of the thermoplastic resin include a plasticized polyvinyl acetal-based resin, a plasticized polyvinyl chloride-based resin, a saturated polyester-based resin, a plasticized saturated polyester-based resin, a polyurethane-based resin, a plasticized polyurethane-based resin, an ethylene-vinyl acetate copolymer-based resin, an ethylene-ethyl acrylate copolymer-based resin, a cycloolefin polymer resin, and an ionomer resin. In addition, a resin composition containing a modified hydrogenated block copolymer described in Japanese Patent No. 6065221 can also be suitably used.

Among these resins, a plasticized polyvinyl acetal-based resin is suitably used due to a superior balance of various performances including transparency, weather resistance, strength, adhesion, penetration resistance, an impact energy absorption capability, moisture resistance, a thermal insulation capability, and a sound insulating capability. The thermoplastic resins may be used alone or two or more may be used in combination. “Plasticized” in the plasticized polyvinyl acetal-based resins described above refers to being plasticized by addition of a plasticizer. A similar description also applies to other plasticized resins.

However, depending on a type of a transparent display apparatus, deterioration may occur due to a specific plasticizer and, in such a case, a resin which does not substantially contain the plasticizer is preferably used as the interlayer 210. Examples of a resin which does not contain a plasticizer include an ethylene-vinyl acetate copolymer-based resin.

Examples of the polyvinyl acetal-based resins described above include a polyvinyl formal resin obtained by reacting polyvinyl alcohol (PVA) with formaldehyde, a polyvinyl acetal-based resin in the narrow sense which is obtained by reacting PVA with acetaldehyde, and a polyvinyl butyral resin (PVB) which is obtained by reacting PVA with n-butyraldehyde and, in particular, PVB may be cited as a suitable example due to a superior balance of various performances including transparency, weather resistance, strength, adhesion, penetration resistance, an impact energy absorption capability, moisture resistance, a thermal insulation capability, and a sound insulating capability. Note that the polyvinyl acetal-based resins may be used alone or two or more may be used in combination.

However, the material of the interlayer 210 is not limited to a thermoplastic resin. In addition, the interlayer 210 may include functional particles of an infrared absorbent, an ultraviolet absorbent, a luminescent agent, or the like. Furthermore, the interlayer 210 may have a color part referred to as a shade band.

In addition, while the interlayers 210a and 210b included in the interlayer 210 are preferably made of a same material, the interlayers 210a and 210b may be made of different materials. The interlayer 210 may have three or more layers. For example, the sound insulating capability of the laminated glass 200 can be improved by further forming an interlayer between the interlayers 210a and 210b and making a shearing modulus of elasticity of the interlayer smaller than a shearing modulus of elasticity of the interlayers 210a and 210b by adjusting a plasticizer or the like. In this case, the shearing moduli of elasticity of the interlayers 210a and 210b may be the same or may differ from each other. Furthermore, at least one of the interlayer 210a and the interlayer 210b may have three or more layers.

A thinnest part of a film thickness of the interlayer 210 is preferably 0.5 mm or more. When the film thickness of the interlayer 210 is 0.5 mm or more, sufficient penetration resistance necessary as a laminated glass is secured. A minimum value of the film thickness of the interlayer 210 is more preferably 0.7 mm or more and even more preferably 1.0 mm or more. In addition, a thickest part of the film thickness of the interlayer 210 is preferably 3.5 mm or less. When a maximum value of the film thickness of the interlayer 210 is 3.5 mm or less, the mass of the laminated glass is prevented from becoming excessively large. The maximum value of the film thickness of the interlayer 210 is more preferably 3.4 mm or less, even more preferably 2.8 mm or less, and particularly preferably 2.6 mm or less.

Next, a manufacturing method of the laminated glass 200 will be described.

First, the interlayers 210a and 210b and the transparent display device 100 are sandwiched between the glass plates 220a and 220b to create a laminate.

Next, for example, the laminate is placed in a rubber bag and bonded at a temperature of 70° C. to 110° C. in a vacuum at a gauge pressure of −65 kPa to −100 kPa.

Note that heating conditions, temperature conditions, and a lamination method are appropriately selected so that the transparent display device 100 does not deteriorate during production.

Furthermore, by performing a pressure bonding process under conditions including a temperature of 100° C. to 150° C. and an absolute pressure of 0.6 MPa to 1.3 MPa, for example, the laminated glass 200 with more superior durability is obtained. However, this pressure bonding process may not be performed in order to simplify processes or in consideration of characteristics of materials to be sealed inside the laminated glass 200.

A total thickness of the laminated glass 200 is preferably 2.8 mm to 10 mm. When the total thickness of the laminated glass 200 is 2.8 mm or more, sufficient stiffness can be secured. In addition, when the total thickness of the laminated glass 200 is 10 mm or less, sufficient transmittance can be obtained and haze can be reduced.

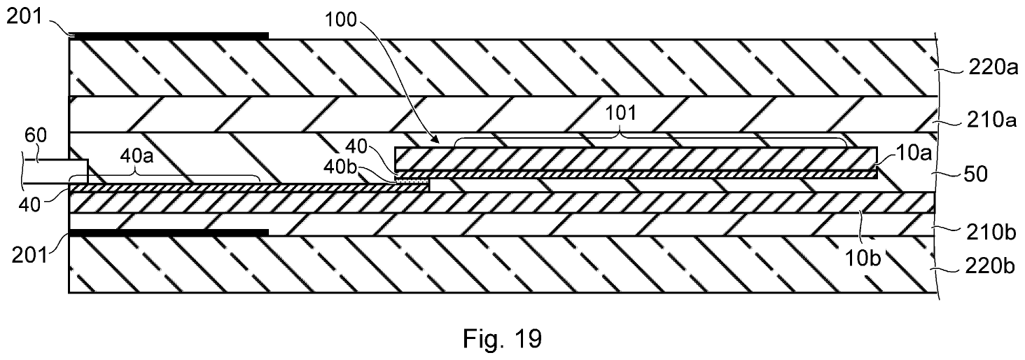

FIG. 19 is a schematic sectional view showing another example of the laminated glass according to the second embodiment. The laminated glass 200 shown in FIG. 19 includes the transparent display device 100 according to the second modified example shown in FIG. 14 in place of the transparent display device 100 according to the first embodiment shown in FIG. 2.

In addition, the protective layer 50 is formed so as to cover the transparent display device 100 in the laminated glass 200. In other words, the protective layer 50 is formed so as to cover the transparent insulating substrate 10a and to enclose the peripheral edge of the transparent insulating substrate 10a. Therefore, the peripheral edge of the transparent insulating substrate 10a becomes less visually recognizable and is preferable. Furthermore, the protective layer 50 may be an interlayer (the third interlayer). Moreover, the protective layer 50 may have transparent resins of different types between a portion which includes a section between the transparent insulating substrate 10a and the transparent insulating substrate 10b and other portions.

A window glass for a vehicle may be an insulating glass in which the laminated glass 200 and at least one or more glass plates are arranged at an interval via a spacer. When the window glass for a vehicle is an insulating glass, a hollow layer is provided between the laminated glass 200 and the glass plate. The hollow layer may be filled with dry air or filled with a rare gas such as krypton or argon. Alternatively, the hollow layer may be a vacuum. When the hollow layer is a vacuum, in order to maintain a gap between the laminated glass 200 and the glass plate, a plurality of gap holding members made of a metal material such as stainless steel or a resin material may be arranged between the laminated glass 200 and the glass plate in a hollow layer region. The spacer may be made of a metal such as aluminum or made of a resin such as polyamide or polypropylene. When the window glass for a vehicle is an insulating glass, the laminated glass 200 may be arranged on a vehicle exterior side or on a vehicle interior side.

In addition, since there are no regulatory provisions regarding visible light transmittance which are applicable to window glasses other than the windshield, the window glasses can be set to any visible light transmittance. Therefore, in the laminated glass 200, a total visible light transmittance of members positioned on the vehicle interior side or the vehicle exterior side of the transparent display device 100 may be set to, for example, 50% or less. Accordingly, the peripheral edges of the transparent insulating substrate 10a and the transparent insulating substrate 10b, the wiring 40, the light-emitting part 20, and the like become less visually recognizable from the vehicle interior side or the vehicle exterior side.

For example, a privacy glass may be used as the glass plate 220a which is positioned on the vehicle interior side. Alternatively, a colored interlayer may be used as the interlayer 210a which is positioned on the vehicle interior side. Furthermore, the laminated glass 200 may be separately provided with a colored film (including a window film) or a dimmer element. A similar description also applies to the glass plate 220b which is positioned on the vehicle exterior side and the interlayer 210b which is positioned on the vehicle exterior side.

A privacy glass is a glass with lower transparency than green glass and clear glass and is also referred to as dark grey colored glass. A privacy glass can be realized by adjusting a total content of iron converted into Fe₂O₃. For example, a visible light transmittance of a privacy glass can be adjusted to around 40% to 50% when a thickness of the privacy glass is 1.8 mm and to around 30% to 45% when the thickness is 2.0 mm.

A detailed description of a privacy glass is provided in, for example, International Patent Publication No. WO 2015/088026, the contents of which are incorporated herein by reference.

A colored interlayer is an interlayer with a lower transparency than a clear interlayer. In this case, the visible light transmittance of the clear interlayer is, for example, around 90% to 95% when the film thickness is 0.76 mm. The colored interlayer is obtained by coloring the materials described above as the interlayer 210. Specifically, the colored interlayer is obtained by causing a composition mainly including a thermoplastic resin to contain a colorant. The colored interlayer may contain a plasticizer for adjusting a glass-transition temperature.

Note that the laminated glass 200 may collectively lower a total visible light transmittance of members positioned on the vehicle exterior side of the transparent display device 100. Accordingly, the peripheral edges of the transparent insulating substrate 10a and the transparent insulating substrate 10b, the wiring 40, the light-emitting part 20, and the like become even less visually recognizable from the vehicle exterior side and also become less visually recognizable from the vehicle interior side. Note that a total visible light transmittance of members positioned on the vehicle interior side of the transparent display device 100 may be collectively lowered. Accordingly, the peripheral edges of the transparent insulating substrate 10a and the transparent insulating substrate 10b, the wiring 40, the light-emitting part 20, and the like become even less visually recognizable from the vehicle interior side and also become less visually recognizable from the vehicle exterior side.

### Third Embodiment

### <Configuration of Transparent Display Device>

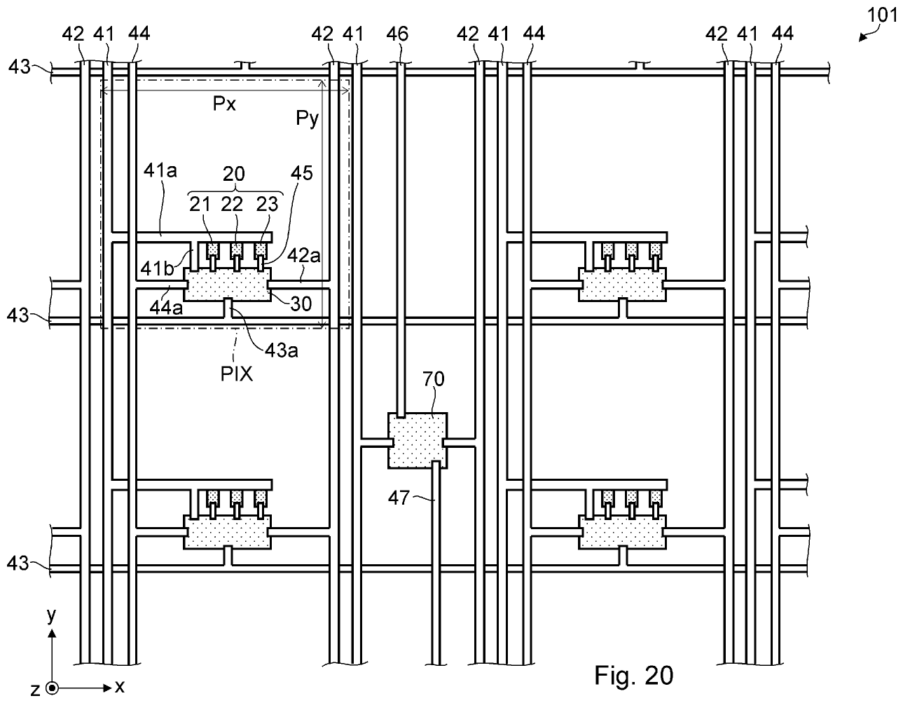

Next, a configuration of a transparent display device according to a third embodiment will be explained with reference to FIG. 20. FIG. 20 is a schematic partial plan view showing an example of the transparent display device according to the third embodiment. As shown in FIG. 20, the transparent display device according to the present embodiment includes a sensor 70 in the display region 101 in addition to the configuration of the transparent display device according to the first embodiment shown in FIG. 3. In other words, the transparent display device has a function as a transparent sensing device.

In the example shown in FIG. 20, the sensor 70 is provided between predetermined pixels PIX and connected to the power supply line 41 and the ground line 42. In addition, detection data detected by the sensor 70 is output via a data output line 46 extending in the y-axis direction from the sensor 70. On the other hand, a control signal is input to the sensor 70 via a control signal line 47 extending to the sensor 70 in the y-axis direction to control the sensor 70. A single sensor 70 or a plurality of sensors 70 may be provided. For example, a plurality of the sensors 70 may be arranged in the x-axis direction or the y-axis direction at predetermined intervals.

Hereinafter, a case where the transparent display device according to the present embodiment is mounted to a windshield among window glasses for an automobile will be described. In other words, the transparent display device according to the present embodiment can also be applied to the laminated glass according to the second embodiment.

For example, the sensor 70 is an illuminance sensor (for example, a light-receiving element) for detecting an illuminance inside the vehicle and outside the vehicle. For example, a brightness of the display region 101 due to the LED elements 21 to 23 is controlled in accordance with the illuminance detected by the sensor 70. For example, the higher the illuminance outside of the vehicle relative to the illuminance inside of the vehicle, the brightness of the display region 101 due to the LED elements 21 to 23 is also set higher. According to such a configuration, visibility of the transparent display device further improves.

In addition, the sensor 70 may be an infrared sensor (for example, a light-receiving element) for detecting a gaze of an observer (for example, a driver) or an image sensor (for example, a CMOS (complementary metal-oxide-semiconductor) image sensor). For example, the transparent display device is driven only when the sensor 70 detects a gaze. For example, the transparent display device is preferably used in the laminated glass shown in FIG. 17 because the transparent display device does not block a field of view of the observer unless the observer directs a gaze toward the transparent display device. Alternatively, a function may be provided in which a motion of the observer is detected by the sensor 70 being an image sensor and, based on the motion, for example, the transparent display device is turned on or off or a displayed screen is switched to another screen.

The configuration is otherwise similar to the transparent display device according to the first embodiment.

### Fourth Embodiment

### <Configuration of Transparent Sensing Device>

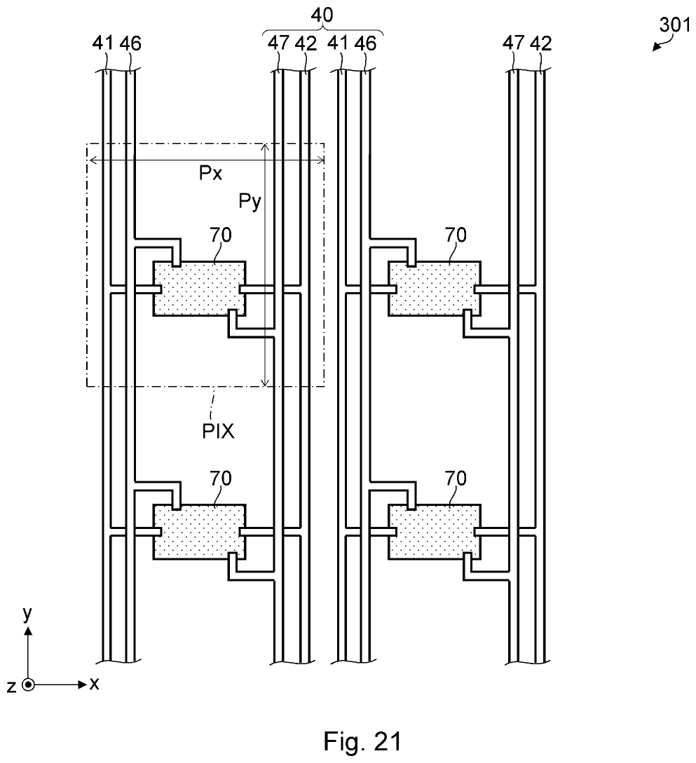

Next, a configuration of a transparent sensing device according to a fourth embodiment will be explained with reference to FIG. 21. FIG. 21 is a schematic partial plan view showing an example of the transparent sensing device according to the fourth embodiment. As shown in FIG. 21, the transparent sensing device according to the present embodiment is configured to include the sensor 70 in place of the light-emitting part 20 and the IC chip 30 in each pixel PIX in the configuration of the transparent display device according to the first embodiment shown in FIG. 3. In other words, the transparent sensing device shown in FIG. 21 does not include the light-emitting part 20 and does not have a display function. The transparent sensing device is an aspect of the transparent electronic device. A sensing region in the transparent sensing device may correspond to the display region 101 in the transparent display device 100.

While the sensor 70 is not particularly limited, the sensor 70 is a CMOS image sensor in the transparent sensing device shown in FIG. 21. In other words, the transparent sensing device shown in FIG. 21 includes an imaging region 301 constituted of a plurality of pixels PIX arranged in a row direction (x-axis direction) and a column direction (y-axis direction) and has an imaging function. FIG. 21 shows a part of the imaging region 301 and shows a total of four pixels constituted of two pixels respectively in the row direction and the column direction. In this case, one pixel PIX is shown enclosed by a dashed-dotted line. In addition, in FIG. 21, the transparent insulating substrate 10a and the protective layer 50 are omitted in a similar manner to FIG. 3. Furthermore, although FIG. 21 is a plan view, the sensor 70 is displayed by dots in order to facilitate understanding.

In the example shown in FIG. 21, one sensor 70 is provided in each pixel PIX, arranged between the power supply line 41 and the ground line 42 extending in the y-axis direction, and connected to both the power supply line 41 and the ground line 42. In addition, detection data detected by the sensor 70 is output via a data output line 46 extending in the y-axis direction from the sensor 70. On the other hand, a control signal is input to the sensor 70 via a control signal line 47 extending to the sensor 70 in the y-axis direction to control the sensor 70. For example, the control signal is a synchronization signal, a reset signal, or the like.

Note that the power supply line 41 may be connected to a battery (not illustrated).

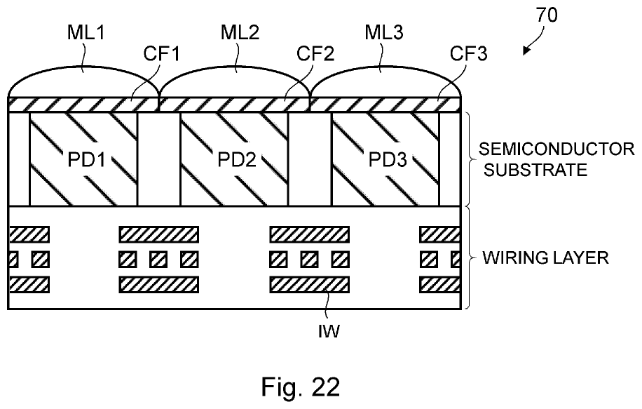

In this case, FIG. 22 is a schematic sectional view of the sensor 70. The sensor 70 shown in FIG. 22 is a back-illuminated CMOS image sensor. Note that the sensor 70 as an image sensor is also not particularly limited and may be a front-illuminated CMOS image sensor or a CCD (charge-coupled device) image sensor.

As shown in FIG. 22, each sensor 70 includes a wiring layer, a semiconductor substrate, color filters CF1 to CF3, and microlenses ML1 to ML3. In this case, an internal wiring IW is formed inside the wiring layer. In addition, photodiodes PD1 to PD3 are formed inside the semiconductor substrate.

The semiconductor substrate (for example, a silicon substrate) is formed on the wiring layer. The internal wiring IW formed inside the wiring layer connects the wiring 40 (the power supply line 41, the ground line 42, the data output line 46, and the control signal line 47) and the photodiodes PD1 to PD3 to each other. When the photodiodes PD1 to PD3 are irradiated with light, electrical currents are output from the photodiodes PD1 to PD3. The electrical currents output from the photodiodes PD1 to PD3 are respectively amplified by an amplifier circuit (not illustrated) and output via the internal wiring IW and the data output line 46.

The color filters CF1 to CF3 are respectively formed on the photodiodes PD1 to PD3 which are formed inside the semiconductor substrate. For example, the color filters CF1 to CF3 are, respectively, a red filter, a green filter, and a blue filter.

The microlenses ML1 to ML3 are respectively placed on the color filters CF1 to CF3. Light collected by the microlenses ML1 to ML3 which are convex lenses is incident to the photodiodes PD1 to PD3 via the color filters CF1 to CF3.

The sensor 70 according to the present embodiment is a microsensor having a minute size of which an occupied area on the transparent insulating substrate 10a is 250,000 μm² or less. In other words, in the present specification, a microsensor is a sensor having a minute size of which an area in a plan view is 250,000 μm² or less. The occupied area of the sensor 70 is, for example, preferably 25,000 μm² or less and more preferably 2,500 μm² or less. Due to various manufacturing conditions and the like, a lower limit of the area occupied by the sensor 70 is, for example, 10 μm² or more.

While a shape of the sensor 70 shown in FIG. 21 is a rectangular shape, the shape of the sensor 70 is not particularly limited.

The transparent sensing device according to the present embodiment can also be applied to the laminated glass according to the second embodiment. When the transparent sensing device according to the present embodiment is mounted to a windshield among window glasses for a vehicle (for example, an automobile), for example, an image of at least any of the inside of the vehicle and the outside of the vehicle can be acquired by the sensor 70. In other words, the transparent sensing device according to the present embodiment has a function as a vehicle traveling data recorder.

Note that the sensor 70 in the transparent sensing device according to the fourth embodiment may be singular. In addition, the sensor 70 in the transparent sensing device according to the fourth embodiment is not limited to an image sensor and may be an illuminance sensor, an infrared sensor, or the like exemplified in the third embodiment. Furthermore, the sensor 70 may be a radar sensor, a Lidar sensor, or the like. For example, the inside of the vehicle and the outside of the vehicle can be monitored by window glasses for a vehicle mounted with the transparent sensing device using the sensor 70 described above.

In other words, the sensor 70 according to the fourth embodiment is not particularly limited as long as the sensor 70 is a microsensor having a minute size of which an occupied area on the transparent insulating substrate 10a is 250,000 μm² or less. For example, the sensor 70 may be a temperature sensor, an ultraviolet light sensor, a radio wave sensor, a pressure sensor, a sound sensor, a speed/acceleration sensor, or the like.

The configuration is otherwise similar to the transparent display device according to the first embodiment.

The present invention is not limited to the embodiments described above and can be appropriately modified without deviating from the scope and spirit of the disclosure.

For example, the transparent display device may have a touch panel function.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A transparent electronic device, comprising:
a transparent insulating substrate;
an electronic element which is formed on a main surface of the transparent insulating substrate and which has an area of 250,000 μm² or less; and
an opaque power feeder configured to feed power to the electronic element, wherein
the electronic element is a light-emitting diode element or a sensor,
the transparent insulating substrate includes:
a first transparent insulating substrate with the electronic element and a first wiring connected to the electronic element being formed on one main surface; and
a second transparent insulating substrate with a second wiring being formed on one main surface,
the electronic element is not formed on the second transparent insulating substrate, and
one end of the first wiring and one end of the second wiring are electrically connected to each other and the opaque power feeder is connected to another end of the second wiring in an edge part of the second transparent insulating substrate.

2. The transparent electronic device according to claim 1, wherein
the first transparent insulating substrate and the second transparent insulating substrate overlap with each other in a plan view, and
the one end of the first wiring and the one end of the second wiring are electrically connected to each other in the overlapping portion of the first transparent insulating substrate and the second transparent insulating substrate.

3. The transparent electronic device according to claim 2, wherein
all of the first transparent insulating substrate overlaps with the second transparent insulating substrate in a plan view.

4. The transparent electronic device according to claim 2, wherein
the one main surface of the first transparent insulating substrate and the one main surface of the second transparent insulating substrate oppose each other and overlap with each other in a plan view.

5. The transparent electronic device according to claim 1, wherein
a region where the electronic element is arranged in the first transparent insulating substrate does not overlap with the second wiring.

6. The transparent electronic device according to claim 1, wherein
the electronic element is a light-emitting diode element, and
the light-emitting diode element constitutes a transparent display device.

7. The transparent electronic device according to claim 1, wherein
the second transparent insulating substrate is flexible.

8. The transparent electronic device according to claim 1, wherein
the one end of the first wiring and the one end of the second wiring are electrically connected to each other via a conductive joining layer.

9. A laminated glass, comprising:
a pair of glass plates arranged so as to oppose each other; and
first and second interlayers provided between the pair of glass plates, wherein
the transparent electronic device according to claim 1 is sandwiched between the first and second interlayers.

10. The laminated glass according to claim 9, wherein
a shielding layer is formed on a peripheral edge of at least one of the pair of glass plates.

11. The laminated glass according to claim 10, wherein
an opaque wiring region in which at least one of the first and second wirings is formed wide and which is opaque is formed on a peripheral edge of the transparent electronic device, and
the opaque wiring region is installed so as to overlap with the shielding layer in a plan view.

12. The laminated glass according to claim 10, wherein
the opaque power feeder is installed so as to overlap with the shielding layer in a plan view.

13. The laminated glass according to any claim 10, wherein
a peripheral edge of at least one of the first and second transparent insulating substrates is installed so as to overlap with the shielding layer in a plan view.

14. The laminated glass according to claim 9, wherein
a protective layer which covers the first transparent insulating substrate is formed between the first and second interlayers.

15. The laminated glass according to claim 14, wherein
the protective layer includes an interlayer which differs from the first and second interlayers.

16. The laminated glass according to claim 9, wherein
the pair of glass plates are curved.

17. The laminated glass according to claim 9, wherein
the laminated glass is for a vehicle, and
a thickness of a glass plate positioned on a vehicle exterior side among the pair of glass plates ranges from 1.5 mm to 3.0 mm.

18. The laminated glass according to claim 9, wherein
a peripheral edge of the first transparent insulating substrate does not overlap with the “Test region A” as defined in Annex “Test regions for optical properties and light resistance tests of safety glass” of JIS Standard R3212:2015 (Test methods of safety glazing materials for road vehicles) in a plane view.

19. The laminated glass according to claim 9, wherein
a peripheral edge of the second transparent insulating substrate does not overlap with the “Test region A” as defined in Annex “Test regions for optical properties and light resistance tests of safety glass” of JIS Standard R3212:2015 (Test methods of safety glazing materials for road vehicles) in a plane view.

20. A manufacturing method of a transparent electronic device, comprising:
forming an electronic element which has an area of 250,000 μm² or less and a first wiring which is connected to the electronic element on one main surface of a first transparent insulating substrate;
forming a second wiring without forming the electronic element on one main surface of a second transparent insulating substrate; and
electrically connecting one end of the first wiring and one end of the second wiring to each other and connecting an opaque power feeder which feeds power to the electronic element to another end of the second wiring in an edge part of the second transparent insulating substrate.
